(19) United States
(12) Patent Application Publication
(10) Pub. No.: US 2025/0120230 A1
(43) Pub. Date: Apr. 10, 2025

(54) OPTICAL STRUCTURE

(71) Applicant: Lextar Electronics Corporation, Hsinchu City (TW)

(72) Inventors: Shu-Ching PENG, Hsinchu City (TW); Yu-Hsi SUNG, Hsinchu City (TW); Jung-Cheng CHANG, Hsinchu City (TW); Wei-Chung CHENG, Hsinchu City (TW); Yin-Cyuan WU, Hsinchu City (TW); Sheng-Fu WANG, Hsinchu City (TW); Wen-Yu LEE, Hsinchu City (TW)

(21) Appl. No.: 18/811,463

(22) Filed: Aug. 21, 2024

(30) Foreign Application Priority Data
Oct. 6, 2023 (TW) 112138595

(51) Int. Cl. H01L 33/60; H01L 33/50

(52) U.S. Cl. CPC H10H 20/856; H10H 20/8514

(57) ABSTRACT

An optical structure is provided. The optical structure includes a substrate, a light-emitting element, a glue layer, and a light-adjusting element. The light-emitting element is disposed on the substrate. The glue layer covers the light-emitting element. The light-adjusting element is disposed on the glue layer. Moreover, the refractive index of the glue layer is different from the refractive index of the light-adjusting element.

### CROSS REFERENCE TO RELATED APPLICATIONS

This application claims the benefit of Taiwan Application No. 112138595, filed Oct. 6, 2023, the entirety of which is incorporated by reference herein.

### BACKGROUND

### Technical Field

The present disclosure is related to an optical structure, and in particular it is related to an optical structure having a light-modulating element and a glue layer.

### Description of the Related Art

Light-emitting diodes (LEDs) are light-emitting elements that are widely used as light sources in various electronic devices. With the extensive application of electronic devices, consumers' expectations for electronic devices have gradually increased.

In order to meet the demand for high resolution and achieve higher production capacity, the size of light-emitting diodes is continuously miniaturized, causing many unresolved problems in the process of manufacturing light-emitting diodes, affecting the performance of light-emitting elements. For example, the current packaging structure of light-emitting diodes still has problems, such as limited light-emitting angle, low light-emitting efficiency, uneven brightness, and uneven color conversion.

Therefore, how to further improve the optical structure of light-emitting diodes to enhance the performance of electronic devices is currently still an important research topic in the industry.

### SUMMARY

In accordance with some embodiments of the present disclosure, an optical structure is provided. The optical structure includes a substrate, a light-emitting element, a glue layer and a light-adjusting element. The light-emitting element is disposed on the substrate. The glue layer covers the light-emitting element. The light-adjusting element is disposed on the glue layer. Moreover, the refractive index of the glue layer is different from the refractive index of the light-adjusting element.

In accordance with some other embodiments of the present disclosure, an optical structure is provided. The optical structure includes a substrate, a light-emitting element, a wavelength conversion layer, a glue layer, and a light-adjusting element. The light-emitting element is disposed on the substrate. The wavelength conversion layer covers the light-emitting element. The glue layer covers the wavelength conversion layer. The light-adjusting element is disposed on the glue layer. Moreover, the refractive index of the wavelength conversion layer is greater than the refractive index of the glue layer, and a width of a top surface of the glue layer is greater than a width of a bottom surface.

In accordance with some other embodiments of the present disclosure, an optical structure is provided. The optical structure includes a substrate, a light-emitting element, a wavelength conversion layer, a glue layer, and an optical component. The light-emitting element is disposed on the substrate. The wavelength conversion layer is disposed on the light-emitting element. The glue layer covers the wavelength conversion layer. The optical component is disposed corresponding to the glue layer. Moreover, the refractive index of the wavelength conversion layer is greater than the refractive index of the glue layer.

A detailed description is given in the following embodiments with reference to the accompanying drawings.

### BRIEF DESCRIPTION OF THE DRAWINGS

The present disclosure may be more fully understood by reading the subsequent detailed description and examples with references made to the accompanying drawings, wherein:

FIG. 1A is a schematic diagram of an optical structure in accordance with some embodiments of the present disclosure;

FIG. 1B is a cross-sectional diagram of an optical structure corresponding to section line A1-A1′ of FIG. 1A in accordance with some embodiments of the present disclosure;

FIG. 2A is a schematic diagram of an optical structure in accordance with some embodiments of the present disclosure;

FIG. 2B is a cross-sectional diagram of an optical structure corresponding to section line A2-A2′ of FIG. 2A in accordance with some embodiments of the present disclosure;

FIG. 3A is a schematic diagram of an optical structure in accordance with some embodiments of the present disclosure;

FIG. 3B is a cross-sectional diagram of an optical structure corresponding to section line A3-A3′ of FIG. 3A in accordance with some embodiments of the present disclosure;

FIG. 4A is a schematic diagram of an optical structure in accordance with some embodiments of the present disclosure;

FIG. 4B is a cross-sectional diagram of an optical structure corresponding to section line A4-A4′ of FIG. 4A in accordance with some embodiments of the present disclosure;

FIG. 5A is a schematic diagram of an optical structure in accordance with some embodiments of the present disclosure;

FIG. 5B is a cross-sectional diagram of an optical structure corresponding to section line A5-A5′ of FIG. 5A in accordance with some embodiments of the present disclosure;

FIG. 6A is a schematic diagram of an optical structure in accordance with some embodiments of the present disclosure;

FIG. 6B is a cross-sectional diagram of an optical structure corresponding to section line A6-A6′ of FIG. 6A in accordance with some embodiments of the present disclosure;

FIG. 7 is a cross-sectional diagram of an optical structure in accordance with some embodiments of the present disclosure;

FIG. 8 is a cross-sectional diagram of an optical structure in accordance with some embodiments of the present disclosure;

FIG. 9 is a cross-sectional diagram of an optical structure in accordance with some embodiments of the present disclosure;

FIG. 10 is a cross-sectional diagram of an optical structure in accordance with some embodiments of the present disclosure;

FIG. 11 is a schematic diagram of an optical structure in accordance with some embodiments of the present disclosure;

FIG. 12 is a schematic diagram of an optical structure in accordance with some embodiments of the present disclosure;

FIG. 13 is a schematic diagram of an optical structure in accordance with some embodiments of the present disclosure;

FIG. 14 is a schematic diagram of an optical structure in accordance with some embodiments of the present disclosure;

FIG. 15 is a schematic diagram of an optical structure in accordance with some embodiments of the present disclosure;

FIG. 16 is a schematic diagram of an optical structure in accordance with some embodiments of the present disclosure;

FIG. 17 is a schematic diagram of an optical structure in accordance with some embodiments of the present disclosure;

FIG. 18A is a light pattern simulation diagram of an optical structure according to Comparative Example 1;

FIG. 18B is a light pattern simulation diagram of an optical structure in accordance with some embodiments of the present disclosure;

FIG. 18C is a light pattern simulation diagram of an optical structure in accordance with some embodiments of the present disclosure;

FIG. 18D is a comparison of results of light pattern simulation of optical structures in accordance with some embodiments of the present disclosure;

FIG. 19A is a light pattern simulation diagram of an optical structure in accordance with some embodiments of the present disclosure;

FIG. 19B is a light pattern simulation diagram of an optical structure in accordance with some embodiments of the present disclosure;

FIG. 19C is a light pattern simulation diagram of an optical structure in accordance with some embodiments of the present disclosure;

FIG. 20 is a comparison result of the brightness distribution of optical structures according to a comparative example and an example of the present disclosure;

FIG. 21A is an image of an optical structure applied to an actual module according to a comparative example;

FIG. 21B is an image of an optical structure applied to an actual module according to an example of the present disclosure;

FIG. 22A is a light pattern simulation diagram of optical structures according to a comparative example and an example of the present disclosure;

FIG. 22B is a comparison result of the brightness distribution of optical structures according to a comparative example and an example of the present disclosure;

FIG. 23 is a cross-sectional diagram of an optical structure in accordance with some embodiments of the present disclosure;

FIG. 24 is a cross-sectional diagram of an optical structure in accordance with some embodiments of the present disclosure;

FIG. 25 is a comparison result of the brightness distribution of optical structures according to a comparative example and an example of the present disclosure;

FIG. 26A and FIG. 26B are respectively an image of the light spot of an optical structure and an image of the optical structure applied to the actual module according to a comparative example;

FIG. 27A and FIG. 27B are respectively an image of the light spot of an optical structure and an image of the optical structure applied to the actual module in accordance with some embodiments of the present disclosure;

FIG. 28A and FIG. 28B are respectively an image of the light spot of an optical structure and an image of the optical structure applied to the actual module in accordance with some embodiments of the present disclosure;

FIG. 29 is a cross-sectional diagram of an optical structure in accordance with some embodiments of the present disclosure;

FIG. 30 is a cross-sectional diagram of an optical structure in accordance with some embodiments of the present disclosure;

FIG. 31 is a cross-sectional diagram of an optical structure in accordance with some embodiments of the present disclosure;

FIG. 32 is a cross-sectional diagram of an optical structure in accordance with some embodiments of the present disclosure;

FIG. 33 is a cross-sectional diagram of an optical structure in accordance with some embodiments of the present disclosure;

FIG. 34 is a cross-sectional diagram of an optical structure in accordance with some embodiments of the present disclosure;

FIG. 35 is a cross-sectional diagram of an optical structure in accordance with

some embodiments of the present disclosure;

FIG. 36 is a cross-sectional diagram of an optical structure in accordance with some embodiments of the present disclosure;

FIG. 37 is a cross-sectional diagram of an optical structure in accordance with

some embodiments of the present disclosure;

FIG. 38 is a cross-sectional diagram of an optical structure in accordance with some embodiments of the present disclosure;

FIG. 39 is a cross-sectional diagram of an optical structure in accordance with some embodiments of the present disclosure;

FIG. 40 is a cross-sectional diagram of an optical structure in accordance with some embodiments of the present disclosure;

FIG. 41 is a cross-sectional diagram of an optical structure in accordance with some embodiments of the present disclosure;

FIG. 42 is a cross-sectional diagram of an optical structure in accordance with some embodiments of the present disclosure;

FIG. 43A and FIG. 43B are respectively an image of the light spot of an optical structure and an image of the optical structure applied to the actual module according to a comparative example;

FIG. 44A and FIG. 44B are respectively an image of the light spot of an optical structure and an image of the optical structure applied to the actual module in accordance with some embodiments of the present disclosure;

FIG. 45 is a schematic diagram of a backlight module in accordance with some embodiments of the present disclosure;

FIG. 46 is a schematic diagram of a backlight module in accordance with some embodiments of the present disclosure;

FIG. 47 is a schematic diagram of a backlight module in accordance with some embodiments of the present disclosure;

FIG. 48 is a schematic diagram of a backlight module in accordance with some embodiments of the present disclosure;

FIG. 49 is a schematic diagram of a backlight module in accordance with some embodiments of the present disclosure.

### DETAILED DESCRIPTION

The optical structures according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers “first”, “second”, etc. mentioned in the specification or claims of the present application are used to name different elements or to distinguish different embodiments or scopes. They are not used to limit the upper or lower limit of the number of elements, nor are they used to limit the manufacturing sequence or disposing sequence of the elements.

In accordance with the embodiments of the present disclosure, regarding the terms such as “disposed”, “connected with/to”, etc. referring to bonding and connection, unless specifically defined, these terms mean that two structures are in direct contact or two structures are not in direct contact, and other structures are provided to be disposed between the two structures. The terms for disposing and connecting may also include the case where both structures are movable or both structures are fixed.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range greater than or equal to the first value and less than or equal to the second value” or “in a range between the first value and the second value” means that the range includes the first value, the second value, and other values in between.

Unless defined otherwise, all technical and scientific terms used herein have the same meaning as commonly understood by one of ordinary skill in the art to which the present disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, the optical structure provided includes a wavelength conversion layer and a glue layer configured in a specific size ratio, thereby improving the luminous efficiency and luminous angle of the light-emitting element and reducing the quantity of light-emitting elements used in a module, and thus the manufacturing costs can be reduced. In accordance with some other embodiments of the present disclosure, the optical structure provided can increase the intensity of the lateral light source and improve the reflection effect of the light source. In accordance with still some embodiments of the present disclosure, the optical structure provided includes a light-adjusting layer and a glue layer configured in a specific size ratio, thereby improving the luminous efficiency and luminous angle of the light-emitting element. In accordance with still some embodiments of the present disclosure, the optical structure provided includes an optical component that can additionally perform wavelength conversion, thereby maintaining a large-angled light pattern and effectively improving the blue halo and yellow halo phenomena.

In accordance with some embodiments of the present disclosure, the optical structure described below can be applied to a backlight module, but the present disclosure is not limited thereto.

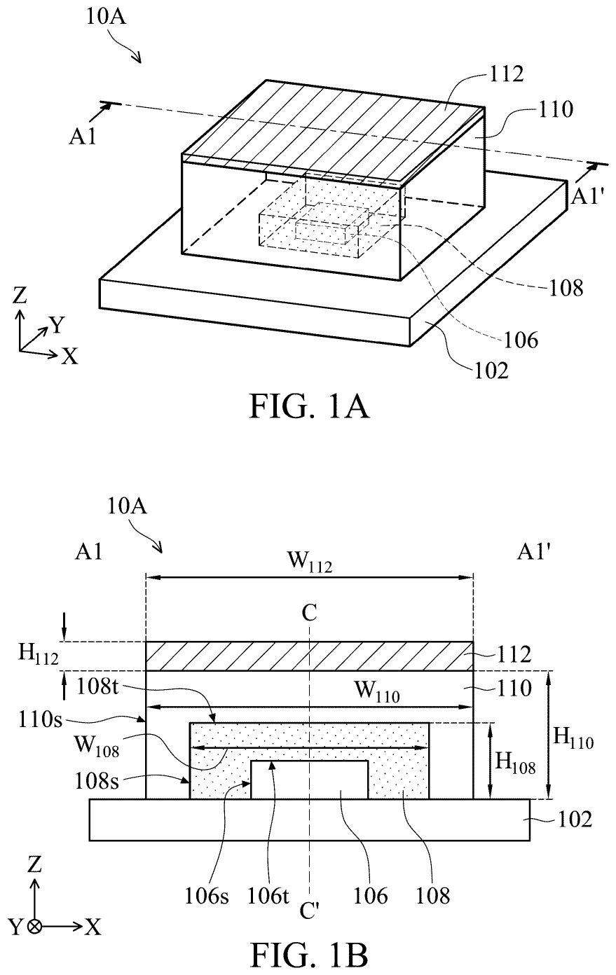

Please refer to FIG. 1A and FIG. 1B. FIG. 1A is a schematic diagram of an optical structure 10A in accordance with some embodiments of the present disclosure. FIG. 1B is a cross-sectional diagram of the optical structure 10A corresponding to section line A1-A1′ of FIG. 1A in accordance with some embodiments of the present disclosure. It should be understood that, for clarity of explanation, some elements of the optical structure may be omitted in the drawings, and only some elements are schematically illustrated. In accordance with some embodiments, additional features may be added to the optical structures described below. In accordance with some embodiments, some features of the optical structure described below may be replaced or omitted.

As shown in FIG. 1A and FIG. 1A 1B, the optical structure 10A includes a substrate 102, a light-emitting element 106, a wavelength conversion layer 108, a glue layer 110, and a light-adjusting element 112.

In accordance with some embodiments, the substrate 102 includes a flexible substrate, a rigid substrate, or a combination thereof. In accordance with some embodiments, the material of the substrate 102 includes glass, quartz, sapphire, ceramic, plastic, polyimide (PI), polycarbonate (PC), polyethylene terephthalate (PET), polypropylene (PP), another suitable material, or a combination thereof, but it is not limited thereto. In addition, the substrate 102 may be a light-transmitting substrate, a semi-light-transmitting substrate, or an opaque substrate. In accordance with some embodiments, the substrate 102 may be a printed circuit board (PCB).

The light-emitting element 106 is disposed on the substrate 102. The light-emitting element 106 is a light-emitting diode such as a mini light-emitting diode (mini-LED). In accordance with some embodiments, the light-emitting element 106 is electrically connected to a driving element (not illustrated) disposed on the substrate 102. The driving element may include an active driving element, a passive driving element, or a combination thereof. The active driving element may include a thin-film transistor (TFT), but the present disclosure is not limited thereto. Furthermore, in the embodiments where the driving element is a passive driving element, the driving element may be controlled by, for example, an integrated circuit (IC) or a microchip, but the present disclosure is not limited thereto. In accordance with some embodiments, the light-emitting element 106 emits blue light, red light, green light, or another suitable color of light, but the present disclosure is not limited thereto. In some embodiments, the light-emitting element 106 is a flip-chip light-emitting diode.

The wavelength conversion layer 108 covers the light-emitting element 106. In detail, the wavelength conversion layer 108 may be in contact with the top surface 106t and the side surface 106s of the light-emitting element 106. The wavelength conversion layer 108 can convert the light generated by the light-emitting element 106 into light with a specific color or specific wavelength. The wavelength conversion layer 108 may have a matrix and one or more wavelength converting substances dispersed in the matrix. In accordance with some embodiments, the matrix includes polymer materials, but it is not limited thereto. In accordance with some embodiments, the wavelength conversion substance includes phosphors, quantum dot materials, or a combination thereof, but it is not limited thereto. Furthermore, in accordance with some embodiments, the light-emitting element 106 is a light-emitting diode emitting blue light, and the wavelength conversion layer 108 includes yellow phosphors. For example, the yellow phosphors may be yttrium aluminum garnet (YAG) phosphors. The optical structure 10A can emit white light, but the present disclosure is not limited thereto. In accordance with some embodiments, the wavelength conversion layer 108 includes red phosphors, green phosphors, another suitable color of phosphors, or a combination thereof, but it is not limited thereto. In accordance with some embodiments, the wavelength conversion layer 108 includes two different types of red phosphors, green phosphors, phosphors of other suitable colors, or a combination thereof, but it is not limited thereto. In accordance with some embodiments, the wavelength conversion layer 108 includes green phosphors and red phosphors. For example, the wavelength conversion layer 108 may include green Sialon phosphors and red K₂SiF₆:Mn⁴⁺. In some embodiments, the wavelength conversion layer 108 includes a combination of green phosphors and two types of red phosphors. For example, the wavelength conversion layer 108 may include green Sialon phosphors, red K₂SiF₆:Mn⁴⁺, and red (Sr,Ca)AlSiN₃:Eu²⁺.

Furthermore, the glue layer 110 covers the wavelength conversion layer 108. In detail, the glue layer 110 may be in contact with the top surface 108t and the side surface 108s of the wavelength conversion layer 108. The glue layer 110 can protect the wavelength conversion layer 108. For example, the glue layer 110 may have a moisture-proof function or an insulation function, which can improve the reliability of the overall structure. The glue layer 110 may include a photo-curing adhesive material, a thermal-curing adhesive material, a photo-thermal-curing adhesive material, or a combination thereof, but it is not limited thereto. In accordance with some embodiments, the material of the glue layer 110 includes an optical clear adhesive (OCA), an optical clear resin (OCR), another suitable material, or a combination thereof, but it is not limited thereto. In accordance with some embodiments, the material of the glue layer 110 includes silicone. The glue layer 110 may be transparent or semi-transparent. In accordance with some embodiments, the glue layer 110 includes diffusion particles. In accordance with some embodiments, the diffusion particles include inorganic particles, organic polymer particles, or a combination thereof. For example, the inorganic particles may include silicon oxide, titanium oxide, titanium dioxide, aluminum oxide, calcium carbonate, barium sulfate, boron nitride, zirconium dioxide, or any combination thereof, but the present disclosure is not limited thereto. For example, the inorganic particles may include solid silica, hollow silica, or any combination thereof, but the present disclosure is not limited thereto. For example, the organic polymer particles may include polymethylmethacrylate (PMMA), polystyrene (PS), acrylonitrile-butadiene-styrene copolymer (ABS), polyurethane (PU), or any combination thereof, but the present disclosure is not limited thereto.

It should be noted that the refractive index of the wavelength conversion layer 108 is different from the refractive index of the glue layer 110, and the refractive index of the wavelength conversion layer 108 is greater than the refractive index of the glue layer 110. Specifically, in accordance with some embodiments, the refractive index of the glue layer 110 is between 1.4 and 1.6, for example, 1.45, 1.5, or 1.55, but it is not limited thereto. In accordance with some embodiments, the refractive index of the wavelength conversion layer 108 is between 1.6 and 2.6, for example, 1.7, 1.8, 1.9, 2, 2.1, 2.2, 2.3, 2.4, or 2.5, but it is not limited thereto. When the refractive index of the wavelength conversion layer 108 and the glue layer 110 have the above relationship, the luminous efficiency of the light-emitting element 106 can be increased, and the light pattern of the optical structure can be improved. In accordance with some embodiments, the ratio of the refractive index of the glue layer 110 to the refractive index of the wavelength conversion layer 108 is less than 1 (i.e., the refractive index of the glue layer 110/the refractive index of the wavelength conversion layer 108<1). In addition, in accordance with some embodiments, the roughness of the side surface 110s of the glue layer 110 is between 0.012 μm and 2 μm, or between 0.02 μm and 1.9 μm, or between 0.05 μm and 1.8 μm, or between 0.1 μm and 1.7 μm, for example, 0.2 μm, 0.3 μm, 0.4 μm, 0.5 μm, 0.6 μm, 0.7 μm, 0.8 μm, 0.9 μm, 1 μm, 1.1 μm, 1.2 μm, 1.3 μm, 1.4 μm, 1.5 μm or 1.6 μm, but it is not limited thereto.

As shown in FIG. 1B, the wavelength conversion layer 108 has a width W₁₀₈, and the glue layer 110 has a width W₁₁₀. In accordance with some embodiments, the ratio of the width W₁₀₈ of the wavelength conversion layer 108 to the width W₁₁₀ of the glue layer 110 is greater than 0 and less than or equal to 0.5 (i.e., 0<W₁₀₈/W₁₁₀≤0.5), for example, 0.05, 0.1, 0.15, 0.2, 0.25, 0.3, 0.35, 0.4 or 0.45, but it is not limited thereto. Furthermore, the wavelength conversion layer 108 has a height H₁₀₈, and the glue layer 110 has a height H₁₁₀. In accordance with some embodiments, the ratio of the height H₁₀₈ of the wavelength conversion layer 108 to the height H₁₁₀ of the glue layer 110 is greater than 0 and less than or equal to 0.5 (i.e., 0<H₁₀₈/H₁₁₀≤0.5), for example, 0.05, 0.1, 0.15, 0.2, 0.25, 0.3, 0.35, 0.4 or 0.45, but it is not limited thereto. It should be noted that when the area of the glue layer 110 covering the wavelength conversion layer 108 is too small, the light-emitting element 106 may emit uneven light; conversely, when the area of the glue layer 110 covering the wavelength conversion layer 108 is too large (for example, W₁₀₈/W₁₁₀>0.5 and/or H₁₀₈/H₁₁₀>0.5), the luminous flux may be reduced, thereby affecting the luminous efficiency of the light-emitting element 106. In other words, when the height and width ratios of the wavelength conversion layer 108 and the glue layer 110 fall within the above ranges (0<W₁₀₈/W₁₁₀≤0.5 and 0<H₁₀₈/H₁₁₀≤0.5), the luminous efficiency of the light-emitting element 106 can be effectively improved and the light pattern of the optical structure can be improved.

In accordance with some embodiments of the present disclosure, the aforementioned width W 108 refers to the maximum width of the wavelength conversion layer 108 in a direction perpendicular to the normal direction of the substrate 102 (for example, the X direction in the figure), and the width W₁₁₀ refers to the maximum width of the glue layer 110 in a direction perpendicular to the normal direction of the substrate 102 (for example, the X direction in the figure). In accordance with some embodiments of the present disclosure, the aforementioned height H₁₀₈ refers to the maximum height of the wavelength conversion layer 108 in the normal direction of the substrate 102 (for example, the Z direction in the figure); and the height H₁₁₀ refers to the maximum height of the glue layer 110 in the normal direction of the substrate 102 (for example, the Z direction in the figure), i.e., the maximum distance between the bottom surface (not labeled) of the light-emitting element 106 and the top surface (not labeled) of the glue layer 110.

In addition, as shown in FIG. 1A and FIG. 1B, the light-adjusting element 112 is disposed on the glue layer 110, and the light-adjusting element 112 is in contact with the glue layer 110. The light-adjusting element 112 can further enhance the luminous intensity of the light-emitting element 106. In accordance with some embodiments, the light-adjusting element 112 has high reflectivity, and the reflectivity of the light-adjusting element 112 may be greater than 90%, for example, 91%, 92%, 93%, 94%, 95%, 96%, 97%, 98%, 99% or 100%. In accordance with some embodiments, the light-adjusting element 112 has a matrix and a high-reflectivity material disposed on the surface of the matrix or in the matrix. The material of the matrix may include an organic material; for example, it may include epoxy resin, acrylic resin such as polymethylmethacrylate (PMMA), benzocyclobutene (BCB), polyimide, polyester, polydimethylsiloxane (PDMS), polyethylene terephthalate (PET), polycarbonate (PC) and another suitable material or a combination thereof, but it is not limited thereto. In accordance with some embodiments, the material of the matrix may include glass. In accordance with some embodiments, the high-reflectivity material may include silver (Ag), aluminum (Al), titanium (Ti), titanium dioxide (TiO₂), another suitable material, or a combination thereof, but it is not limited thereto. In accordance with some embodiments, the high-reflectivity material may include thermos-curing high-reflective silicone, but it is not limited thereto. In some embodiments, the light-adjusting element 112 is partially reflective and partially transmissive. In some embodiments, in the Z direction, the light-adjusting element 112 and the glue layer 110 are substantially coplanar.

Furthermore, the light-adjusting element 112 may have a height H₁₁₂. In accordance with some embodiments, the height H₁₁₂ of the light-adjusting element 112 may be between 10 μm and 300 μm, or between 50 μm and 250 μm, for example, 100 μm, 150 μm or 200 μm, but it is not limited thereto. In addition, the light-adjusting element 112 has a width W₁₁₂, and the ratio of the width W₁₁₂ of the light-adjusting element 112 to the width W₁₁₀ of the glue layer 110 may be greater than 0 and less than or equal to 1 (i.e., 0<W₁₁₂/W₁₁₀≤1). In accordance with some embodiments of the present disclosure, the aforementioned width W₁₁₂ refers to the maximum width of the light-adjusting element 112 in a direction perpendicular to the normal direction of the substrate 102 (for example, the X direction in the figure); the height H₁₁₂ refers to the maximum height of the light-adjusting element 112 in the normal direction of the substrate 102 (for example, the Z direction in the figure). In this embodiment, the width W₁₁₂ of the light-adjusting element 112 is substantially equal to the width W₁₁₀ of the glue layer 110. That is, the ratio of the width W₁₁₂ of the light-adjusting element 112 to the width W₁₁₀ of the glue layer 110 is substantially equal to 1. Furthermore, in this embodiment, the light-adjusting element 112 is conformally disposed above the glue layer 110 and has a flat-plate shape, but it is not limited thereto.

Furthermore, the refractive index of the glue layer 110 is different from the refractive index of the light-adjusting element 112. In accordance with some embodiments, the refractive index of the light-adjusting element 112 may be greater than the refractive index of the glue layer 110. In accordance with some embodiments, the light-adjusting element 112 may have a symmetrical structure. In accordance with some embodiments, the optical structure 10A may be a symmetrical structure, such as having a central axis C-C′. The elements of the optical structure 10A can take the central axis C-C′ as the symmetry axis, and have any suitable shape according to needs. In some embodiments, the optical structure 10A may include a bracket 104. The bracket 104 can increase the optical efficiency, and because the bottom contact area of the bracket 104 is larger, the yield rate of placing the optical structure 10A on the substrate 102 is increased. It should be understood that the optical structures in the embodiments of the present disclosure may include the bracket 104 or not include the bracket 104. The detailed structure of the bracket 104 will be further described below.

Other aspects of the optical structures of the embodiments of the present disclosure will be further described below. It should be understood that elements that are identical or similar to those mentioned above will be denoted by the same or similar numerals, and their materials, features and functions are the same or similar to those described above, and thus will not be repeated in the following description.

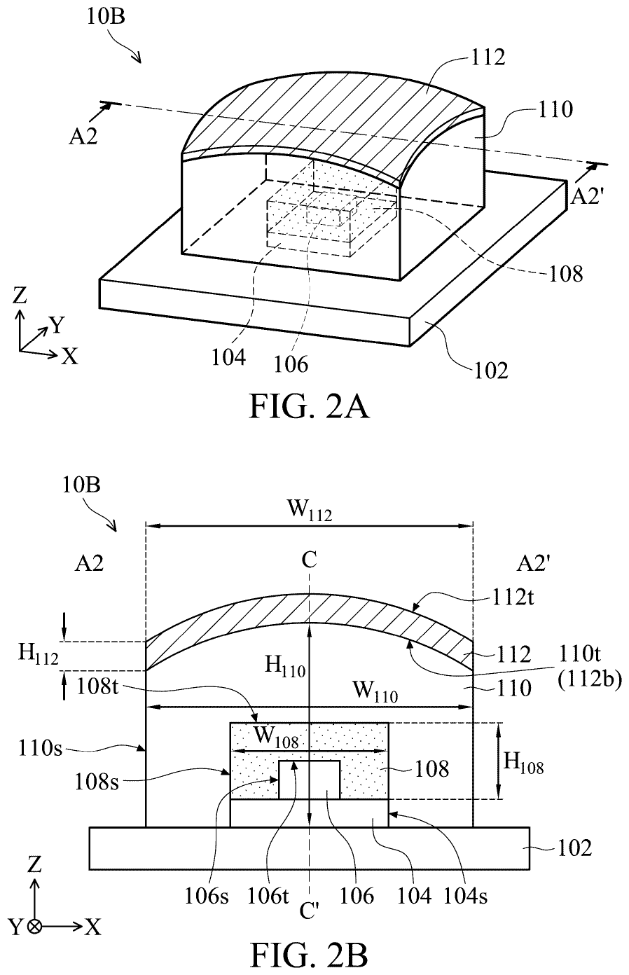

Please refer to FIG. 2A and FIG. 2B. FIG. 2A is a schematic diagram of an optical structure 10B in accordance with some other embodiments of the present disclosure. FIG. 2B is a cross-sectional diagram of the optical structure 10B corresponding to section line A2-A2′ of FIG. 2A in accordance with some embodiments of the present disclosure.

The optical structure 10B is substantially similar to the optical structure 10A. Compared with the optical structure 10A, the optical structure 10B further includes a bracket 104. The bracket 104 may be disposed between the substrate 102 and the light-emitting element 106. The bracket 104 may be disposed between the substrate 102 and the wavelength conversion layer 108. As shown in FIG. 2B, in accordance with some embodiments, the side surface 108s of the wavelength conversion layer 108 and the side surface 104s of the bracket 104 are substantially coplanar, but the present disclosure is not limited thereto. In accordance with some other embodiments, the side surface 108s of the wavelength conversion layer 108 is not coplanar with the side surface 104s of the bracket 104. For example, the side surface 104s of the bracket 104 may protrude beyond the side surface 108s of the wavelength conversion layer 108. In accordance with some embodiments, the side surface 104s of the bracket 104 is substantially coplanar with the side surface 110s of the transparent glue layer 110. Furthermore, in accordance with some embodiments, the bracket 104 may have a flat-plate shape. It should be noted that the generally used groove-type bracket can only emit light in the forward direction, so the luminous efficiency is low and the light-emitting angle is small. In comparison, the flat bracket 104 in the embodiments of the present disclosure can increase the intensity of the lateral light source, improve the luminous efficiency, and reduce the number used when applied to the module, thereby reducing the manufacturing cost. In some embodiments, the optical structure 10B may not include bracket 104. In the embodiments without the bracket 104, the optical structure 10B can have better heat dissipation and lower manufacturing costs.

In addition, compared with the optical structure 10A, the glue layer 110 of the optical structure 10B has a curved surface. For example, the glue layer 110 of the optical structure 10B may have a curved top surface 110t. Furthermore, the light-adjusting element 112 may be conformally disposed on the glue layer 110, so the light-adjusting element 112 may also have a curved surface. For example, the light-adjusting element 112 of the optical structure 10B may have a curved top surface 112t and a curved bottom surface 112b. In some embodiments, in the Z direction, the side surface of the curved light-adjusting element 112 and the side surface of the glue layer 110 are substantially coplanar.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. This configuration can enhance the luminous efficiency of the light-emitting element 106 and improve the light pattern of the optical structure.

Similarly, in this embodiment, the ratio of the width W₁₀₈ of the wavelength conversion layer 108 to the width W₁₁₀ of the glue layer 110 may be greater than 0 and less than or equal to 0.5 (i.e., 0<W₁₀₈/W₁₁₀≤0.5), for example, 0.05, 0.1, 0.15, 0.2, 0.25, 0.3, 0.35, 0.4 or 0.45, but it is not limited thereto. Furthermore, the ratio of the height H₁₀₈ of the wavelength conversion layer 108 to the height H₁₁₀ of the glue layer 110 may be greater than 0 and less than or equal to 0.5 (i.e., 0<H₁₀₈/H₁₁₀≤0.5), for example, 0.05, 0.1, 0.15, 0.2, 0.25, 0.3, 0.35, 0.4 or 0.45, but it is not limited thereto. It should be understood that in the embodiments in which the optical structure has the bracket 104, the height H₁₁₀ refers to the maximum height of the glue layer 110 plus the bracket 104 in the normal direction of the substrate 102 (for example, the Z direction in the figure), i.e., the maximum distance from the bottom surface (not labeled) of the bracket 104 to the top surface 110t of the glue layer 110.

It should be noted that when the height and width ratios of the wavelength conversion layer 108 and the glue layer 110 fall within the above range (0<W₁₀₈/W₁₁₀≤0.5 and 0<H₁₀₈/H₁₁₀≤0.5), the luminous efficiency of the light-emitting element 106 can be effectively enhanced and the light pattern of the optical structure can be improved. In addition, in this embodiment, the ratio of the width W₁₁₂ of the light-adjusting element 112 to the width W₁₁₀ of the glue layer 110 is substantially equal to 1.

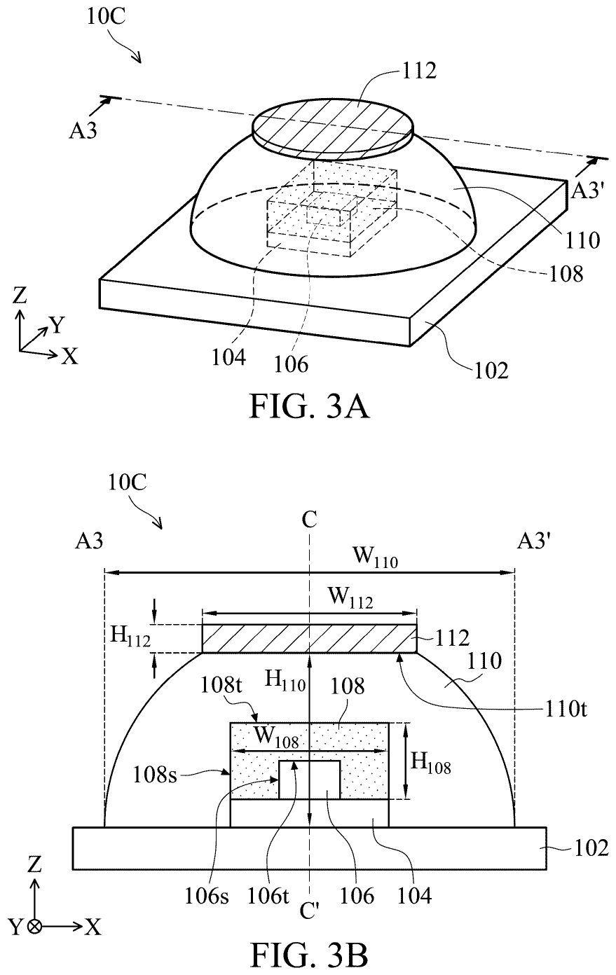

Next, please refer to FIG. 3A and FIG. 3B. FIG. 3A is a schematic diagram of an optical structure 10C in accordance with some other embodiments of the present disclosure. FIG. 3B is a cross-sectional diagram of the optical structure 10C corresponding to section line A3-A3′ of FIG. 3A in accordance with some embodiments of the present disclosure.

The optical structure 10C is substantially similar to the optical structure 10A. Compared with the optical structure 10A, the optical structure 10C further includes a bracket 104, and the glue layer 110 has a curved surface. For example, the glue layer 110 may be in the shape of a hemisphere. Specifically, the glue layer 110 is generally semi-spherical but has a flat top surface 110t. Furthermore, in this embodiment, the light-adjusting element 112 may be disk-shaped, and the light-adjusting element 112 may be disposed on the top surface 110t of the glue layer 110. In this embodiment, the width W₁₁₂ of the light-adjusting element 112 is substantially the same as the width (not labeled) of the top surface 110t of the glue layer 110. In some embodiments, the optical structure 10C may not include the bracket 104.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. This configuration can enhance the luminous efficiency of the light-emitting element 106 and improve the light pattern of the optical structure.

Similarly, in this embodiment, the ratio of the width W₁₀₈ of the wavelength conversion layer 108 to the width W₁₁₀ of the glue layer 110 may be greater than 0 and less than or equal to 0.5 (i.e., 0<W₁₀₈/W₁₁₀≤0.5), for example, 0.05, 0.1, 0.15, 0.2, 0.25, 0.3, 0.35, 0.4 or 0.45, but it is not limited thereto. Furthermore, the ratio of the height H₁₀₈ of the wavelength conversion layer 108 to the height H₁₁₀ of the glue layer 110 may be greater than 0 and less than or equal to 0.5 (i.e., 0<H₁₀₈/H₁₁₀≤0.5), for example, 0.05, 0.1, 0.15, 0.2, 0.25, 0.3, 0.35, 0.4 or 0.45, but it is not limited thereto. It should be noted that when the height and width ratios of the wavelength conversion layer 108 and the glue layer 110 fall within the above range (0<W₁₀₈/W₁₁₀<0.5 and 0<H₁₀₈/H₁₁₀<0.5), the luminous efficiency of the light-emitting element 106 can be effectively enhanced and the light pattern of the optical structure can be improved. In addition, in this embodiment, the ratio of the width W₁₁₂ of the light-adjusting element 112 to the width W₁₁₀ of the glue layer 110 is greater than 0 and less than 1.

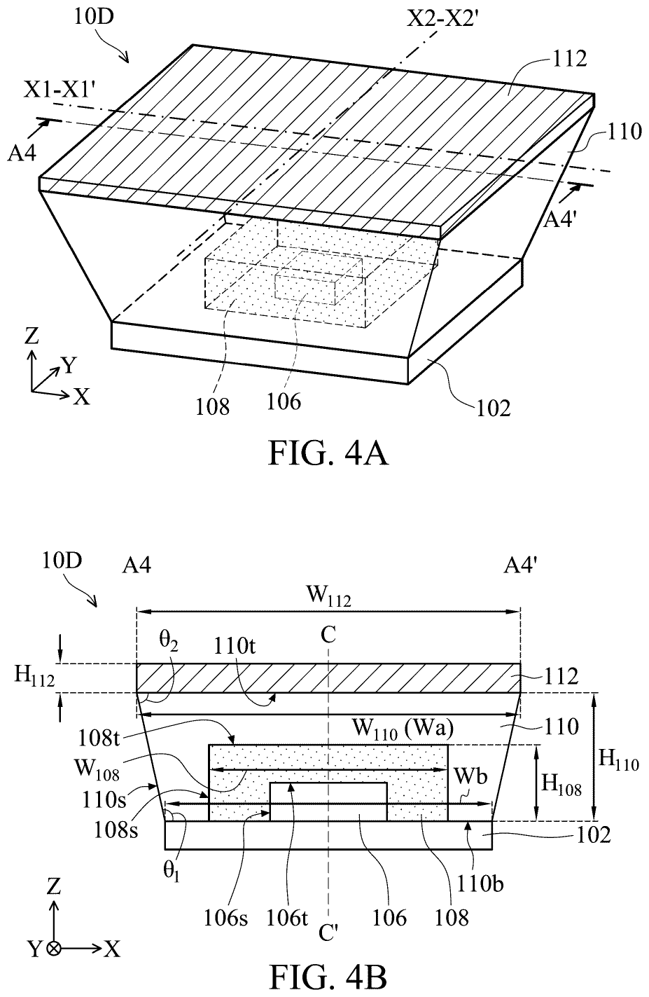

Next, please refer to FIG. 4A and FIG. 4B. FIG. 4A is a schematic diagram of an optical structure 10D in accordance with some other embodiments of the present disclosure. FIG. 4B is a cross-sectional diagram of the optical structure 10D corresponding to section line A4-A4′ of FIG. 4A in accordance with some embodiments of the present disclosure.

The optical structure 10D is substantially similar to the optical structure 10A. Compared with the optical structure 10A, the width Wa of the top surface 110t of the glue layer 110 of the optical structure 10D may be greater than the width Wb of the bottom surface 110b. In other words, the glue layer 110 of the optical structure 10D may have a trapezoidal shape. In this embodiment, the light-adjusting element 112 may have a flat-plate shape, and the light-adjusting element 112 may be disposed on the top surface 110t of the glue layer 110. In this embodiment, the width Wa of the top surface 110t of the glue layer 110 is equal to the width W₁₁₂ of the light-adjusting element 112. Furthermore, in accordance with some embodiments, the width Wa of the top surface 110t of the glue layer 110 may be greater than the width W₁₀₈ of the wavelength conversion layer 108. In accordance with some embodiments, the width Wb of the bottom surface 110b of the glue layer 110 may be greater than the width W₁₀₈ of the wavelength conversion layer 108. In accordance with some embodiments, the height H₁₀₈ of the wavelength conversion layer 108 may be less than or equal to the height H₁₁₀ of the glue layer 110. In this embodiment, the ratio of the width W₁₁₂ of the light-adjusting element 112 to the width W₁₁₀ of the glue layer 110 is substantially equal to 1.

In addition, as shown in FIG. 4B, there is an included angle θ₁ between the side surface 110s and the bottom surface 110b of the glue layer 110, and there is an included angle θ₂ between the side surface 110s and the top surface 110t of the glue layer 110. In this embodiment, the included angle θ₁ between the side surface 110s and the bottom surface 110b of the glue layer 110 is greater than 90 degrees and less than or equal to 150 degrees (i.e. 90 degrees<included angle θ₁≤150 degrees), and the included angle θ₂ between the side surface 110s and the top surface 110t of the glue layer 110 is greater than or equal to 30 degrees and less than 90 degrees (i.e. 30 degrees<included angle θ₂≤90 degrees). In this embodiment, the side surface 110s of the glue layer 110 is inclined. In particular, through the aforementioned configuration, the light-emitting element 106 can have a larger light-emitting angle, which can further improve the light pattern of the optical structure.

In accordance with some embodiments, the light-adjusting element 112 may have a symmetrical structure. For example, the light-adjusting element 112 may have a symmetry axis X1-X1′ and a symmetry axis X2-X2′, and have any suitable shape according to needs. Furthermore, the optical structure 10D may be a symmetrical structure, for example, having a central axis C-C′. The elements of the optical structure 10D can take the central axis C-C′ as the symmetry axis and have any suitable shape according to needs.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. Furthermore, the refractive index of the glue layer 110 is different from the refractive index of the light-adjusting element 112, and the refractive index of the light-adjusting element 112 may be greater than the refractive index of the glue layer 110. This configuration can enhance the luminous efficiency of the light-emitting element 106 and improve the light pattern of the optical structure. In some embodiments, the optical structure 10D may include a bracket 104.

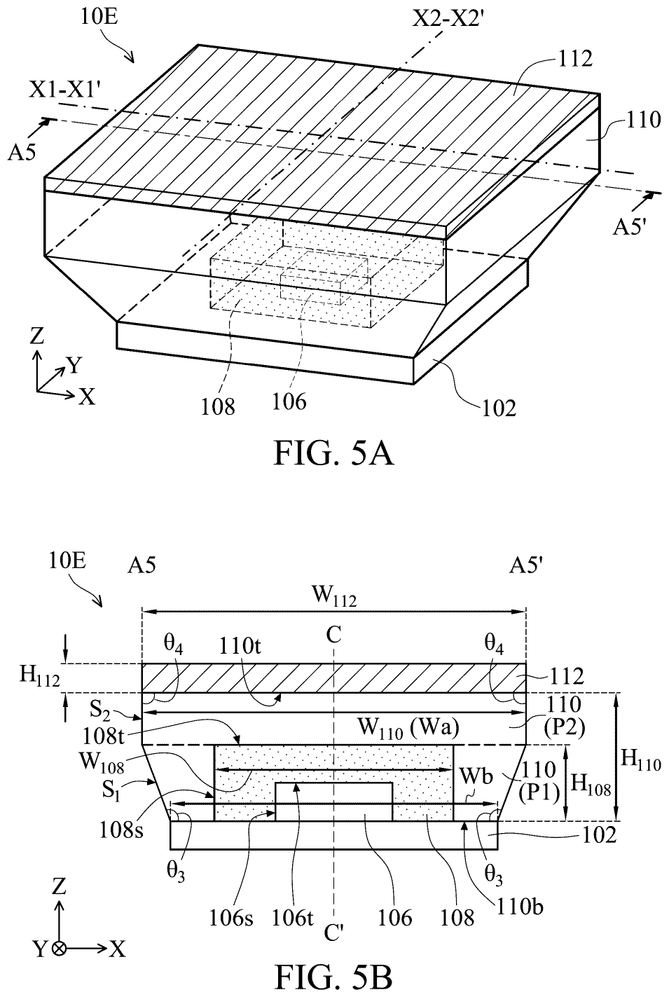

Next, please refer to FIG. 5A and FIG. 5B. FIG. 5A is a schematic diagram of an optical structure 10E in accordance with some other embodiments of the present disclosure. FIG. 5B is a cross-sectional diagram of the optical structure 10E corresponding to section line A5-A5′ of FIG. 5A in accordance with some embodiments of the present disclosure.

The optical structure 10E is substantially similar to the optical structure 10A. Compared with the optical structure 10A, the width Wa of the top surface 110t of the glue layer 110 of the optical structure 10E may be greater than the width Wb of the bottom surface 110b. In this embodiment, the light-adjusting element 112 may have a flat-plate shape, and the light-adjusting element 112 may be disposed on the top surface 110t of the glue layer 110. In this embodiment, the width Wa of the top surface 110t of the glue layer 110 is equal to the width W₁₁₂ of the light-adjusting element 112. Furthermore, in accordance with some embodiments, the width Wa of the top surface 110t of the glue layer 110 may be greater than the width W₁₀₈ of the wavelength conversion layer 108. In accordance with some embodiments, the width Wb of the bottom surface 110b of the glue layer 110 may be greater than the width W₁₀₈ of the wavelength conversion layer 108. In accordance with some embodiments, the height H₁₀₈ of the wavelength conversion layer 108 may be less than or equal to the height H₁₁₀ of the glue layer 110.

In addition, as shown in FIG. 5B, the glue layer 110 of the optical structure 10E may further include a first portion P1 and a second portion P2 disposed on the first portion P1. Furthermore, the first portion P1 has a side surface S₁, the second portion P2 has a side surface S₂, and the side surface S₁ of the first portion P1 and the side surface S₂ of the second portion P2 are not coplanar. Furthermore, there is an included angle θ₃ between the side surface S₁ of the first portion P1 of the glue layer 110 and the bottom surface 110b of the glue layer 110, and there is an angle θ₄ between the side surface S₂ of the second portion P2 of the glue layer 110 and the top surface 110t of the glue layer 110. In this embodiment, the included angle θ₃ between the side surface S₁ of the first portion P1 and the bottom surface 110b of the glue layer 110 is greater than 90 degrees and less than or equal to 150 degrees (i.e., 90 degrees<included angle θ₃≤150 degrees). In this embodiment, the included angle θ₄ between the side surface S₂ of the second portion P2 and the top surface 110t of the glue layer 110 is substantially equal to 90 degrees (i.e., the included angle θ₄=90 degrees). In this embodiment, the side surface S₁ of the first portion P1 of the glue layer 110 is inclined, and the side surface S₂ of the second portion P2 of the glue layer 110 is substantially vertical to the top surface 110t of glue layer 110. In particular, through the aforementioned configuration, the light-emitting element 106 can have a larger light-emitting angle, which can further improve the light pattern of the optical structure.

In accordance with some embodiments, the light-adjusting element 112 may have a symmetrical structure. For example, the light-adjusting element 112 may have a symmetry axis X1-X1′ and a symmetry axis X2-X2′, and have any suitable shape according to needs. In this embodiment, the ratio of the width W₁₁₂ of the light-adjusting element 112 to the width W1₁₀ of the glue layer 110 is substantially equal to 1. In some embodiments, in the Z direction, the side surface S₂ of the second portion P2 of the glue layer 110 and the side surface of the light-adjusting element 112 are substantially coplanar. Furthermore, the optical structure 10E may be a symmetrical structure, for example, having a central axis C-C′. The elements of the optical structure 10E can take the central axis C-C′ as the symmetry axis, and have any suitable shape according to needs.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. Furthermore, the refractive index of the glue layer 110 is different from the refractive index of the light-adjusting element 112, and the refractive index of the light-adjusting element 112 may be greater than the refractive index of the glue layer 110. In other words, the ratio of the refractive index of the glue layer 110 to the refractive index of the light-adjusting element 112 is less than 1. This configuration can enhance the luminous efficiency of the light-emitting element 106 and improve the light pattern of the optical structure. In some embodiments, the optical structure 10E may include a bracket 104.

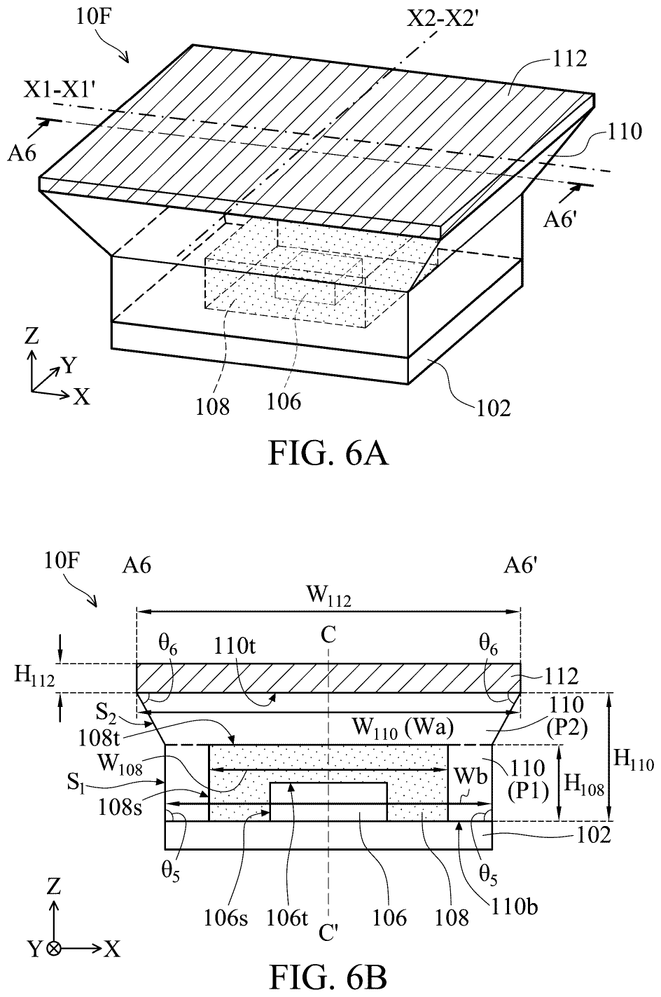

Next, please refer to FIG. 6A and FIG. 6B. FIG. 6A is a schematic diagram of an optical structure 10F in accordance with some other embodiments of the present disclosure. FIG. 6B is a cross-sectional diagram of the optical structure 10F corresponding to section line A6-A6′ of FIG. 6A in accordance with some embodiments of the present disclosure.

The optical structure 10F is substantially similar to the optical structure 10A. Compared with the optical structure 10A, the width Wa of the top surface 110t of the glue layer 110 of the optical structure 1OF may be greater than the width Wb of the bottom surface 110b. In this embodiment, the light-adjusting element 112 may have a flat-plate shape, and the light-adjusting element 112 may be disposed on the top surface 110t of the glue layer 110. In this embodiment, the width Wa of the top surface 110t of the glue layer 110 is equal to the width W₁₁₂ of the light-adjusting element 112. Furthermore, in accordance with some embodiments, the width Wa of the top surface 110t of the glue layer 110 may be greater than the width W₁₀₈ of the wavelength conversion layer 108. In accordance with some embodiments, the width Wb of the bottom surface 110b of the glue layer 110 may be greater than the width W₁₀₈ of the wavelength conversion layer 108. In accordance with some embodiments, the height H₁₀₈ of the wavelength conversion layer 108 may be less than or equal to the height H₁₁₀ of the glue layer 110.

Moreover, as shown in FIG. 6B, the glue layer 110 of the optical structure 10F may further include a first portion P1 and a second portion P2 disposed on the first portion P1. Furthermore, the first portion P1 has a side surface S₁, the second portion P2 has a side surface S₂, and the side surface S₁ of the first portion P1 and the side surface S₂ of the second portion P2 are not coplanar. Specifically, there is an included angle θ₅ between the side surface S₁ of the first portion P1 of the glue layer 110 and the bottom surface 110b of the glue layer 110, and there is an angle θ₆ between the side surface S₂ of the second portion P2 of the glue layer 110 and the top surface 110t of the glue layer 110. In this embodiment, the included angle θ₅ between the side surface S₁ of the first portion P1 and the bottom surface 110b of the glue layer 110 is substantially equal to 90 degrees (i.e., the included angle θ₅=90 degrees). In this embodiment, the included angle θ₆ between the side surface S₂ of the second portion P2 and the top surface 110t of the glue layer 110 is greater than or equal to 30 degrees and less than 90 degrees (i.e., 30 degrees≤included angle θ₆<90 degrees). In this embodiment, the side surface S₁ of the first portion P1 and the bottom surface 110b of the glue layer 110 are substantially vertical, and the side surface S₂ of the second portion P2 and the top surface 110t of the glue layer 110 are inclined. In particular, through the aforementioned configuration, the light-emitting element 106 can have a larger light-emitting angle, which can further improve the light pattern of the optical structure.

In accordance with some embodiments, the light-adjusting element 112 may have a symmetrical structure. For example, the light-adjusting element 112 may have a symmetry axis X1-X1′ and a symmetry axis X2-X2′, and have any suitable shape according to needs. In this embodiment, the ratio of the width W₁₁₂ of the light-adjusting element 112 to the width W₁₁₀ of the glue layer 110 is substantially equal to 1. Furthermore, the optical structure 10F may be a symmetrical structure, for example, having a central axis C-C′. The elements of the optical structure 10F can take the central axis C-C′ as the symmetry axis, and have any suitable shape according to needs.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. Furthermore, the refractive index of the glue layer 110 is different from the refractive index of the light-adjusting element 112, and the refractive index of the light-adjusting element 112 may be greater than the refractive index of the glue layer 110. In other words, the ratio of the refractive index of the glue layer 110 to the refractive index of the light-adjusting element 112 is less than 1. This configuration can enhance the luminous efficiency of the light-emitting element 106 and improve the light pattern of the optical structure. In some embodiments, the optical structure 1OF may include a bracket 104.

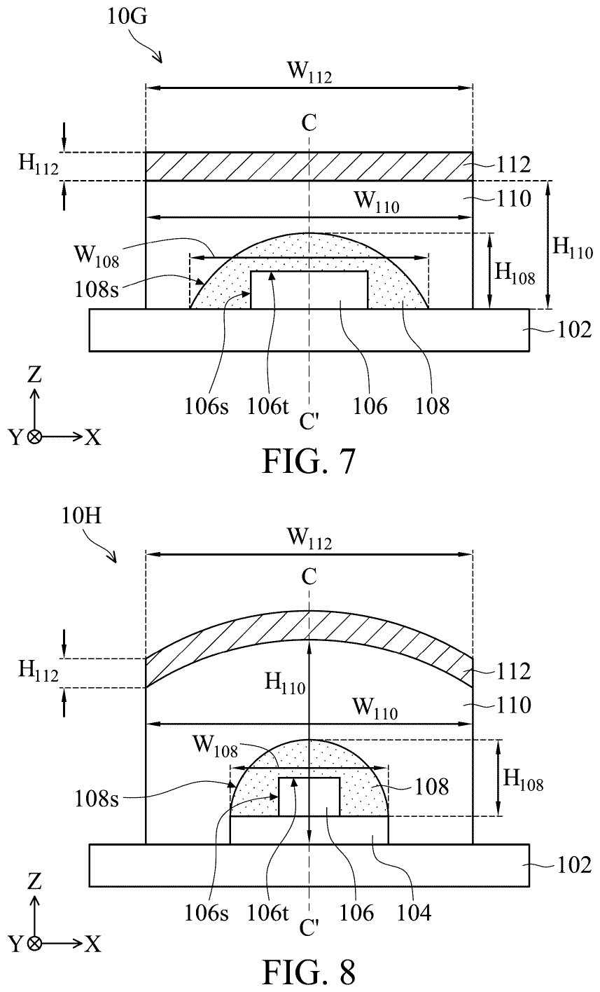

Next, please refer to FIG. 7, which is a cross-sectional diagram of an optical structure 10G in accordance with some other embodiments of the present disclosure. The optical structure 10G is substantially similar to the optical structure 10A. Compared with the optical structure 10A, the wavelength conversion layer 108 of the optical structure 10G has a curved surface. The wavelength conversion layer 108 may be in the shape of a hemisphere, but the present disclosure is not limited thereto.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. This configuration can enhance the luminous efficiency of the light-emitting element 106 and improve the light pattern of the optical structure.

Similarly, in this embodiment, the ratio of the width W₁₀₈ of the wavelength conversion layer 108 to the width W₁₁₀ of the glue layer 110 may be greater than 0 and less than or equal to 0.5 (i.e., 0<W₁₀₈/W₁₁₀≤0.5), for example, 0.05, 0.1, 0.15, 0.2, 0.25, 0.3, 0.35, 0.4 or 0.45, but it is not limited thereto. Furthermore, the ratio of the height H₁₀₈ of the wavelength conversion layer 108 to the height H₁₁₀ of the glue layer 110 may be greater than 0 and less than or equal to 0.5 (i.e., 0<H₁₀₈/H₁₁₀≤0.5), for example, 0.05, 0.1, 0.15, 0.2, 0.25, 0.3, 0.35, 0.4 or 0.45, but it is not limited thereto. It should be noted that when the height and width ratios of the wavelength conversion layer 108 and the glue layer 110 fall within the above range (0<W₁₀₈/W₁₁₀<0.5 and 0<H₁₀₈/H₁₁₀≤0.5), the luminous efficiency of the light-emitting element 106 can be effectively enhanced and the light pattern of the optical structure can be improved. In some embodiments, the optical structure 10G may include a bracket 104.

Next, please refer to FIG. 8, which is a cross-sectional diagram of an optical structure 10H in accordance with some other embodiments of the present disclosure. The optical structure 10H is substantially similar to the optical structure 10B. Compared with the optical structure 10B, the wavelength conversion layer 108 of the optical structure 10H has a curved surface. The wavelength conversion layer 108 may be in the shape of a hemisphere, but the present disclosure is not limited thereto.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. This configuration can enhance the luminous efficiency of the light-emitting element 106 and improve the light pattern of the optical structure.

Similarly, in this embodiment, the ratio of the width W₁₀₈ of the wavelength conversion layer 108 to the width W₁₁₀ of the glue layer 110 may be greater than 0 and less than or equal to 0.5 (i.e., 0<W₁₀₈/W₁₁₀≤0.5), for example, 0.05, 0.1, 0.15, 0.2, 0.25, 0.3, 0.35, 0.4 or 0.45, but it is not limited thereto. Furthermore, the ratio of the height H₁₀₈ of the wavelength conversion layer 108 to the height H₁₁₀ of the glue layer 110 may be greater than 0 and less than or equal to 0.5 (i.e., 0<H₁₀₈/H₁₁₀≤0.5), for example, 0.05, 0.1, 0.15, 0.2, 0.25, 0.3, 0.35, 0.4 or 0.45, but it is not limited thereto. It should be noted that when the height and width ratios of the wavelength conversion layer 108 and the glue layer 110 fall within the above range (0<W₁₀₈/W₁₁₀≤0.5 and 0<H₁₀₈/H₁₁₀≤0.5), the luminous efficiency of the light-emitting element 106 can be effectively enhanced and the light pattern of the optical structure can be improved. In some embodiments, the optical structure 10H may not include a bracket 104.

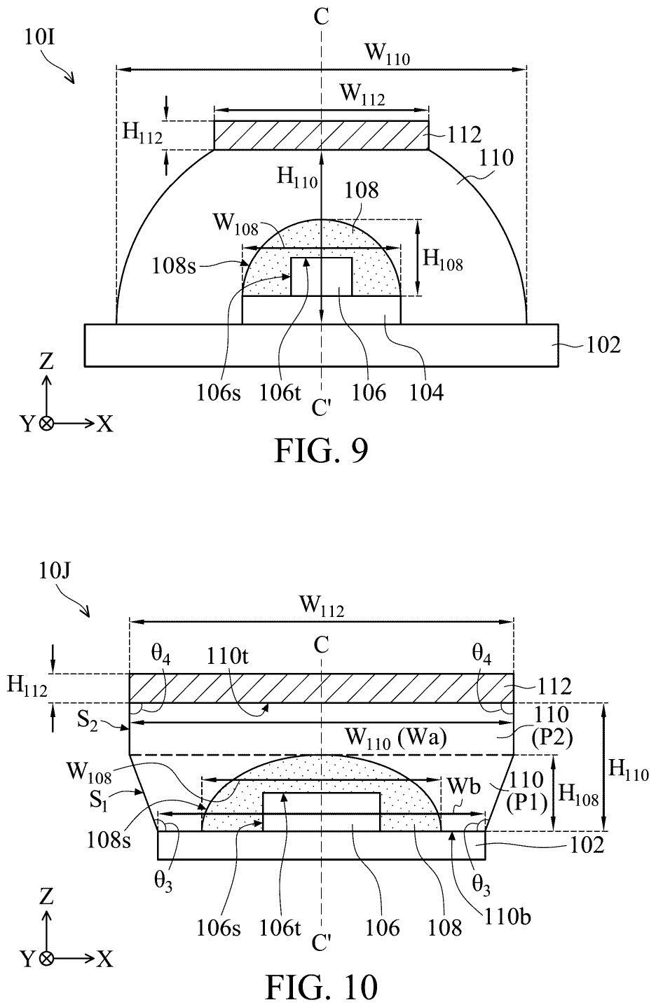

Next, please refer to FIG. 9, which is a cross-sectional diagram of an optical structure 10I in accordance with some other embodiments of the present disclosure. The optical structure 10I is substantially similar to the optical structure 10C. Compared with the optical structure 10C, the wavelength conversion layer 108 of the optical structure 101 has a curved surface. The wavelength conversion layer 108 may be in the shape of a hemisphere, but the present disclosure is not limited thereto.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. This configuration can enhance the luminous efficiency of the light-emitting element 106 and improve the light pattern of the optical structure.

Similarly, in this embodiment, the ratio of the width W₁₀₈ of the wavelength conversion layer 108 to the width W₁₁₀ of the glue layer 110 may be greater than 0 and less than or equal to 0.5 (i.e., 0<W₁₀₈/W₁₁₀≤0.5), for example, 0.05, 0.1, 0.15, 0.2, 0.25, 0.3, 0.35, 0.4 or 0.45, but it is not limited thereto. Furthermore, the ratio of the height H₁₀₈ of the wavelength conversion layer 108 to the height H₁₁₀ of the glue layer 110 may be greater than 0 and less than or equal to 0.5 (i.e., 0<H₁₀₈/H₁₁₀≤0.5), for example, 0.05, 0.1, 0.15, 0.2, 0.25, 0.3, 0.35, 0.4 or 0.45, but it is not limited thereto. It should be noted that when the height and width ratios of the wavelength conversion layer 108 and the glue layer 110 fall within the above range (0<W₁₀₈/W₁₁₀<0.5 and 0<H₁₀₈/H₁₁₀≤0.5), the luminous efficiency of the light-emitting element 106 can be effectively improved and the light pattern of the optical structure can be improved.

Next, please refer to FIG. 10, which is a cross-sectional diagram of an optical structure 10J in accordance with some other embodiments of the present disclosure. The optical structure 10J is substantially similar to the optical structure 10E. Compared with the optical structure 10E, the wavelength conversion layer 108 of the optical structure 10J has a curved surface. The wavelength conversion layer 108 may be in the shape of a hemisphere, but the present disclosure is not limited thereto.

Similarly, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. This configuration can enhance the luminous efficiency of the light-emitting element 106 and improve the light pattern of the optical structure. In some embodiments, the optical structure 10J may include a bracket 104.

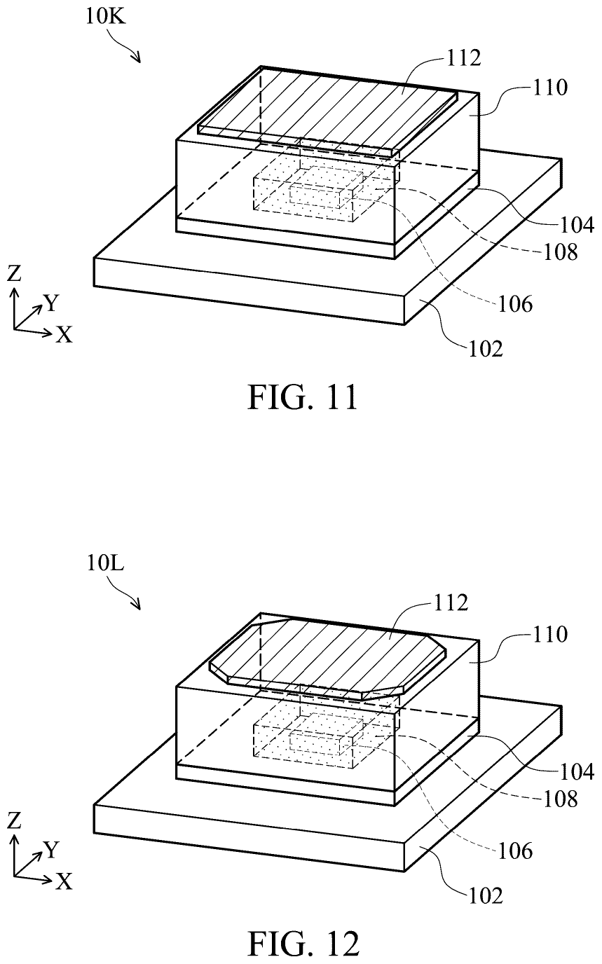

Next, please refer to FIG. 11, which is a schematic diagram of an optical structure 10K in accordance with some other embodiments of the present disclosure. The optical structure 10K is substantially similar to the optical structure 10A. Compared with the optical structure 10A, the optical structure 10K further includes a bracket 104, and the area of the light-adjusting element 112 is smaller than the area of the top surface 110t (not labeled) of the glue layer 110. Furthermore, in this embodiment, the light-adjusting element 112 may have a flat-plate shape. In the top view, the light-adjusting element 112 and the glue layer 110 may have the same shape; for example, they may be rectangular, but the present disclosure is not limited thereto. In some embodiments, the optical structure 10K may not include the bracket 104.

Next, please refer to FIG. 12, which is a schematic diagram of an optical structure 10L in accordance with some other embodiments of the present disclosure. The optical structure 10L is substantially similar to the optical structure 10A. Compared with the optical structure 10A, the optical structure 10K further includes a bracket 104, and the area of the light-adjusting element 112 is smaller than the area of the top surface 110t (not labeled) of the glue layer 110. Furthermore, in this embodiment, the light-adjusting element 112 may have a flat-plate shape, and the light-adjusting element 112 and the glue layer 110 may have different shapes in the top view. For example, the light-adjusting element 112 may have an octagonal shape, and the glue layer 110 may have a rectangular shape, but the present disclosure is not limited thereto. In some embodiments, the optical structure 10L may not include the bracket 104.

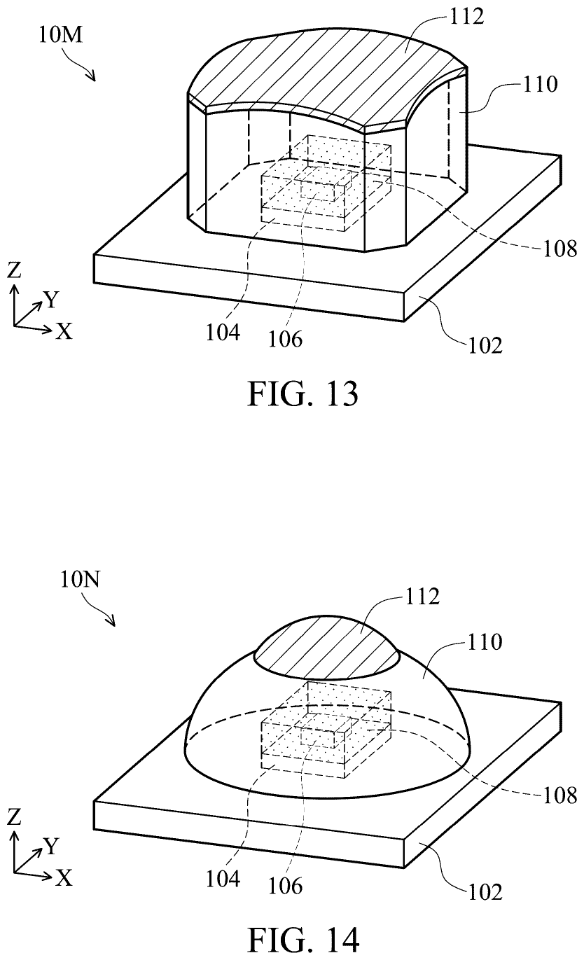

Next, please refer to FIG. 13, which is a schematic diagram of an optical structure 10M in accordance with some other embodiments of the present disclosure. The optical structure 10M is substantially similar to the optical structure 10B, but the glue layer 110 and the light-adjusting element 112 of the optical structure 10M and the optical structure 10B have different shapes. Specifically, in the top-view diagram, the glue layer 110 and the light-adjusting element 112 of the optical structure 10B may be quadrangular, and the glue layer 110 and the light-adjusting element 112 of the optical structure 10M may be octagonal, but the present disclosure is not limited thereto. In some embodiments, the optical structure 10M may not include the bracket 104.

Next, please refer to FIG. 14, which is a schematic diagram of an optical structure 10N in accordance with some other embodiments of the present disclosure. The optical structure 10N is substantially similar to the optical structure 10C, but the light-adjusting elements 112 of the optical structure 10N and the optical structure 10C have different shapes. Specifically, the light-adjusting element 112 of the optical structure 10C may have a flat-plate shape, and the light-adjusting element 112 of the optical structure 10N may have a convex shape; and in the top-views, the light-adjusting elements 112 of the optical structure 10C and the optical structure 10N both may be circular, but the present disclosure is not limited thereto. In some embodiments, the optical structure 10N may not include the bracket 104.

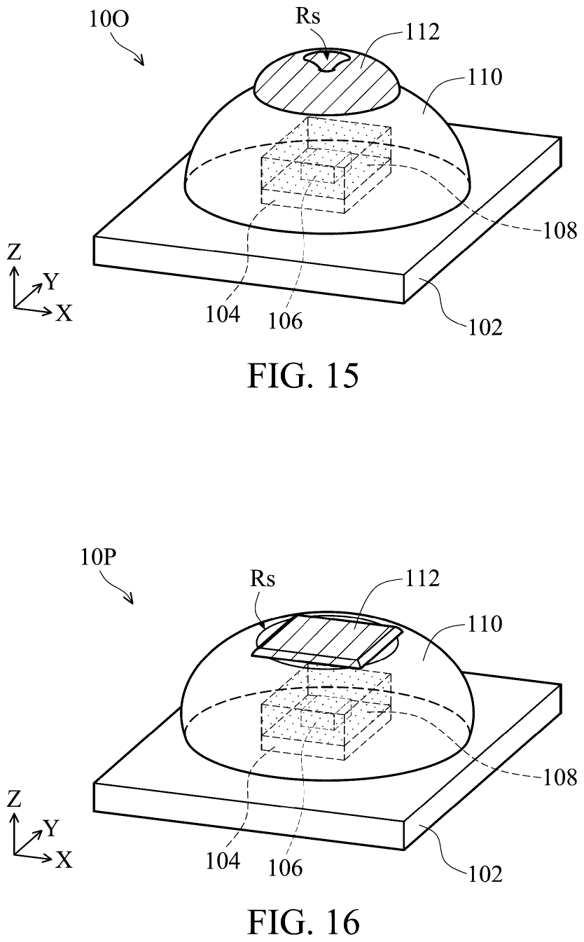

Next, please refer to FIG. 15, which is a schematic diagram of an optical structure 10O in accordance with some other embodiments of the present disclosure. The optical structure 10O is substantially similar to the optical structure 10N. Compared with the optical structure 10N, the light-adjusting element 112 of the optical structure 10O further has a recess Rs, and the recess Rs may be disposed on the top of the light-adjusting element 112. In some embodiments, the optical structure 10O may not include the bracket 104.

Next, please refer to FIG. 16, which is a schematic diagram of an optical structure 10P in accordance with some other embodiments of the present disclosure. The optical structure 10P is substantially similar to the optical structure 10N. Compared with the optical structure 10N, the glue layer 110 of the optical structure 10P further has a recess Rs, and the recess Rs may be disposed on the top of the glue layer 110. Furthermore, in this embodiment, the area of the light-adjusting element 112 is smaller than the area of the bottom surface 110b (not labeled) of the glue layer 110. In other words, the projection of the light-adjusting element 112 on the substrate 102 is smaller than that of the glue layer 110 on the substrate 102. Furthermore, in this embodiment, the light-adjusting element 112 may have a flat-plate shape, and the light-adjusting element 112 and the glue layer 110 can have different shapes in the top view. For example, the light-adjusting element 112 may be quadrangular, and the glue layer 110 may be circular, but the present disclosure is not limited thereto. In some embodiments, the optical structure 10P may not include the bracket 104.

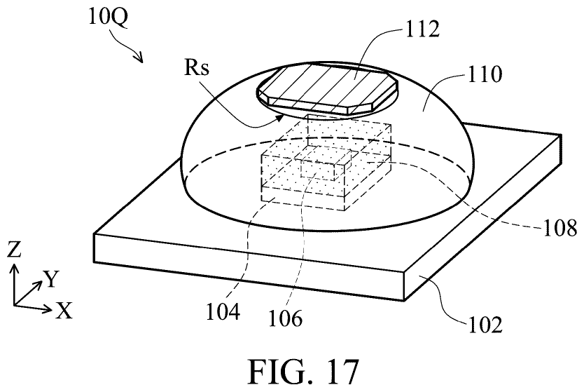

Next, please refer to FIG. 17, which is a schematic diagram of an optical structure 10Q in accordance with some other embodiments of the present disclosure. The optical structure 10Q is substantially similar to the optical structure 10N. Compared with the optical structure 10N, the glue layer 110 of the optical structure 10Q further has a recess Rs, and the recess Rs may be disposed on the top of the glue layer 110. Furthermore, in this embodiment, the area of the light-adjusting element 112 is smaller than the area of the bottom surface 110b (not labeled) of the glue layer 110. In other words, the projection of the light-adjusting element 112 on the substrate 102 is smaller than the projection of the glue layer 110 on the substrate 102. Furthermore, in this embodiment, the light-adjusting element 112 may have a flat-plate shape, and the light-adjusting element 112 and the glue layer 110 may have different shapes in the top view. For example, the light-adjusting element 112 may have an octagonal shape, and the glue layer 110 may be circular, but the present disclosure is not limited thereto.

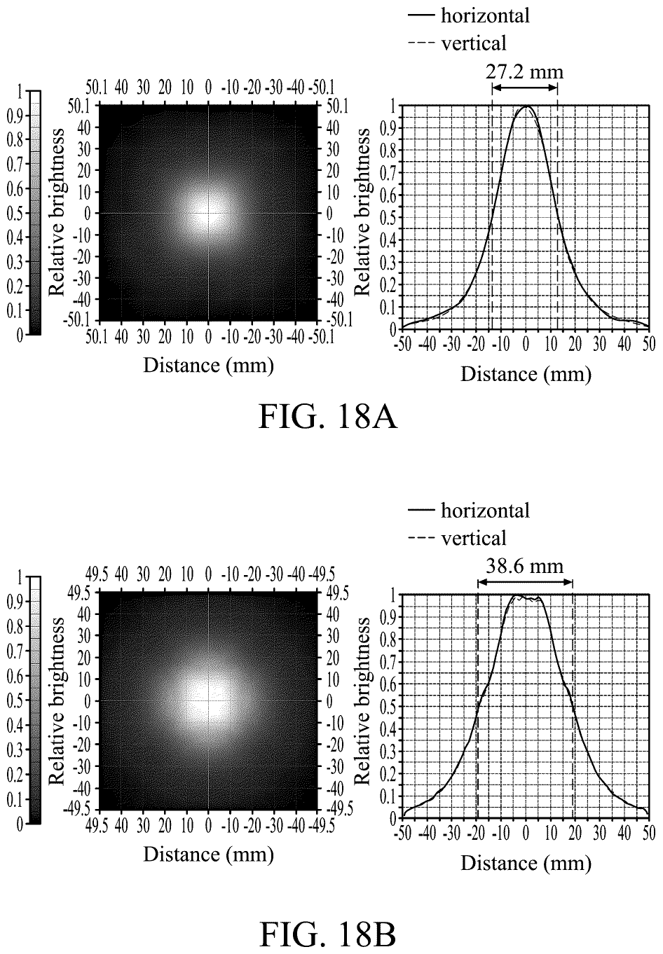

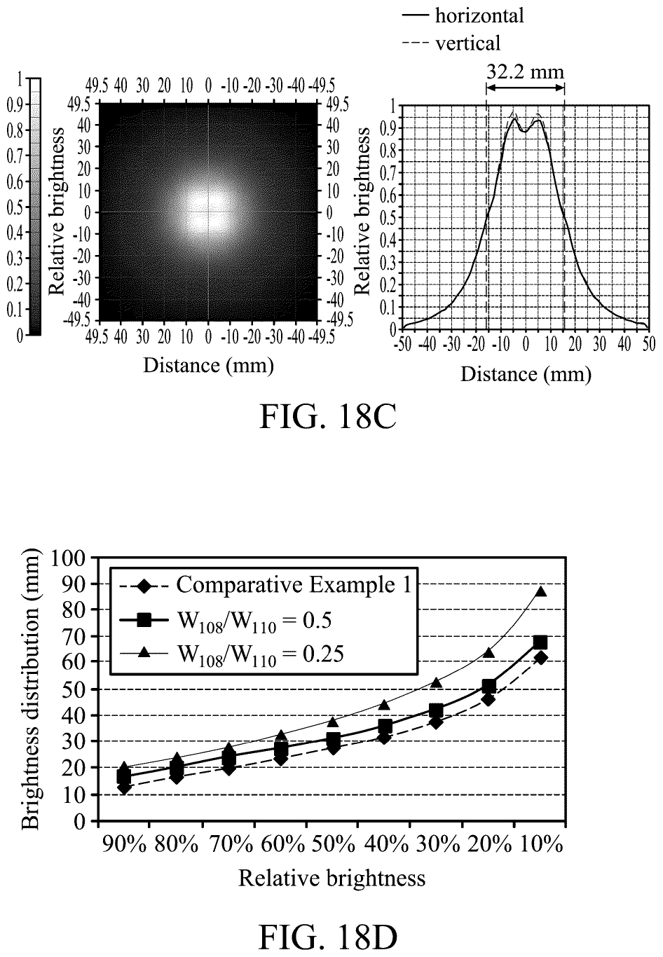

Next, please refer to FIG. 18A, FIG. 18B and FIG. 18C. FIG. 18A is a light pattern simulation diagram of an optical structure according to a comparative example. FIG. 18B and FIG. 18C are light pattern simulation diagrams of optical structures in accordance with some embodiments of the present disclosure. Specifically, FIG. 18A is the light pattern simulation results of the optical structure of Comparative Example 1 (for example, a white LED with a light-emitting element and a wavelength conversion layer sealed in a bracket with a tapered sidewall) (referred to as Comparative Example 1). FIG. 18B is the light pattern simulation results when the ratio of the width of the wavelength conversion layer to the width of the glue layer (W₁₀₈/W₁₁₀) in the optical structure is 0.25. FIG. 18C is the light pattern simulation results when the ratio of the width of the wavelength conversion layer to the width of the glue layer (W₁₀₈/W₁₁₀) in the optical structure is 0.5. Furthermore, the aforementioned results are the results of simulation using LightTools simulation software. As shown in FIGS. 18A to 18C, compared to Comparative Example 1, when the ratio of the width of the wavelength conversion layer to the width of the glue layer (W₁₀₈/W₁₁₀) is 0.25 or 0.5, the overall light pattern and light spot of the optical structure is larger. Furthermore, please refer to FIG. 18D, which is a quantitative curve graph of the aforementioned light pattern simulation results. As shown in FIG. 18D, compared to Comparative Example 1, when the ratio of the width of the wavelength conversion layer to the width of the glue layer is 0.25 or 0.5, the overall brightness of the optical structure is higher, and it also has a larger light pattern and light spot.

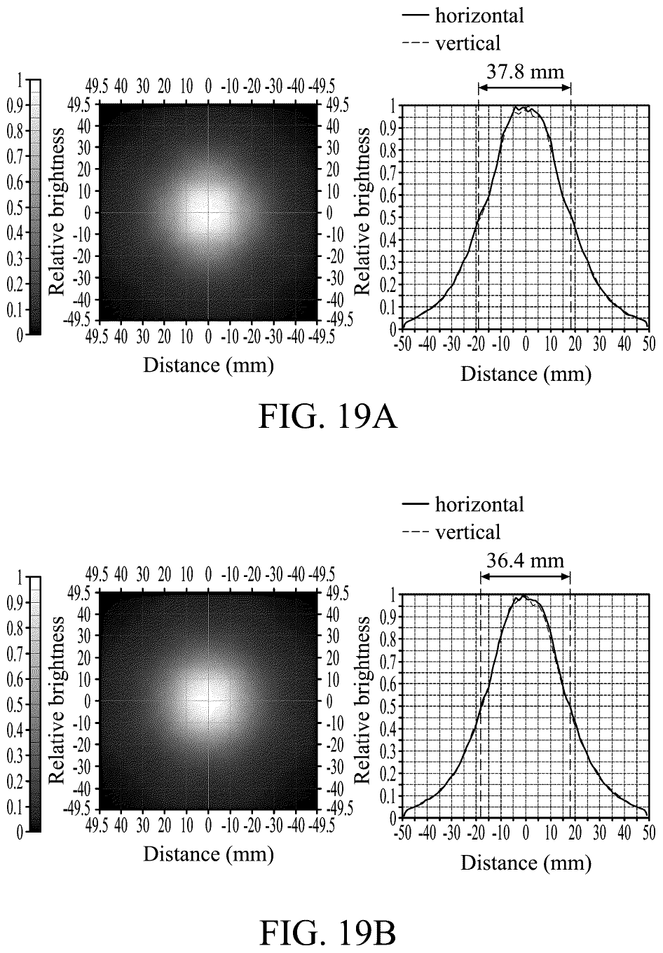

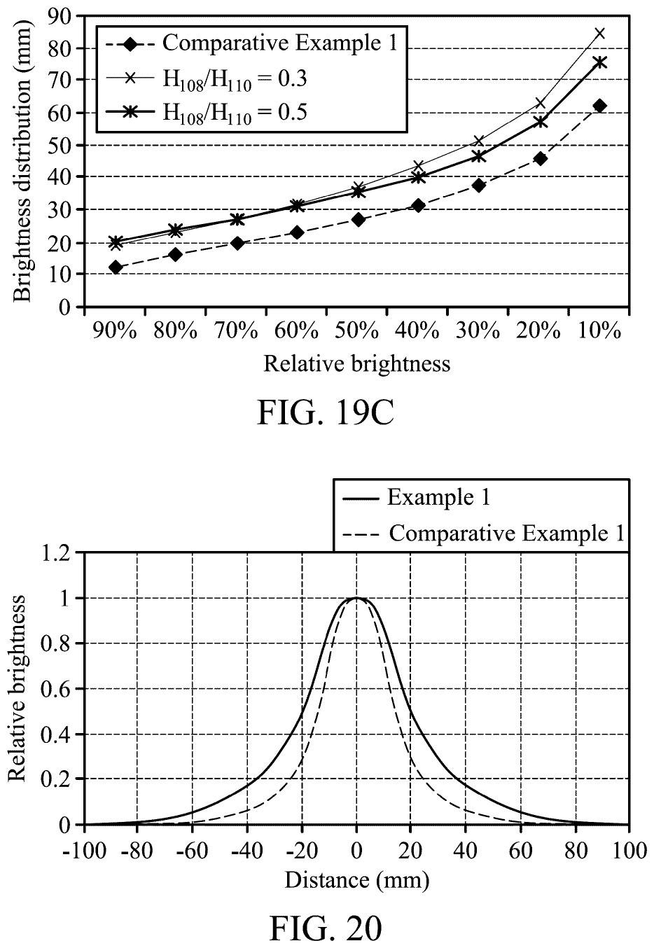

Please refer to FIG. 19A and FIG. 19B, which are light pattern simulation diagrams of optical structures in accordance with some embodiments of the present disclosure. Specifically, FIG. 19A is the light pattern simulation results when the ratio of the width of the wavelength conversion layer to the width of the glue layer (W₁₀₈/W₁₁₀) is 0.25 and the ratio of the height of the wavelength conversion layer to the height of the glue layer (H₁₀₈/H₁₁₀) is 0.3 in the optical structure. FIG. 19B is the light pattern simulation results when the ratio of the width of the wavelength conversion layer to the width of the glue layer (W₁₀₈/W₁₁₀) is 0.25 and the ratio of the height of the wavelength conversion layer to the height of the glue layer (H₁₀₈/H₁₁₀) is 0.5 in the optical structure. Furthermore, the aforementioned results are also the results of simulation using LightTools simulation software. As shown in FIG. 19A and FIG. 19B, compared to Comparative Example 1 (referring to FIG. 18A), when the ratio of the width of the wavelength conversion layer to the width of the glue layer (W₁₀₈/W₁₁₀) is 0.25 and the height of the wavelength conversion layer to the height of the glue layer (H₁₀₈/H₁₁₀) is 0.3 or 0.5, the overall light pattern and light spot of the optical structure are larger. Furthermore, please refer to FIG. 19C, which is a quantitative curve graph of the aforementioned light pattern simulation results. As shown in FIG. 19C, compared with Comparative Example 1, when the ratio of the width of the wavelength conversion layer to the width of the glue layer (W₁₀₈/W₁₁₀) is 0.25 and the ratio of the height of the wavelength conversion layer to the height of the glue layer (H₁₀₈/H₁₁₀) is 0.3 or 0.5, the overall brightness of the optical structure is higher, and it also has a larger light pattern and light spot.

Next, please refer to FIG. 20, which is a comparison result of the brightness distribution of the optical structures according to a comparative example (Comparative Example 1) and an example of the present disclosure (Example 1). Specifically, Example 1 is the brightness distribution result when the ratio of the width of the wavelength conversion layer to the width of the glue layer (W₁₀₈/W₁₁₀) is ≤0.5 and the ratio of the height of the wavelength conversion layer to the height of the glue layer (H₁₀₈/H₁₁₀) is ≤0.5 in the optical structure. As shown in FIG. 20, compared with Comparative Example 1, the brightness distribution of the optical structure of Example 1 of the present disclosure is more uniform.

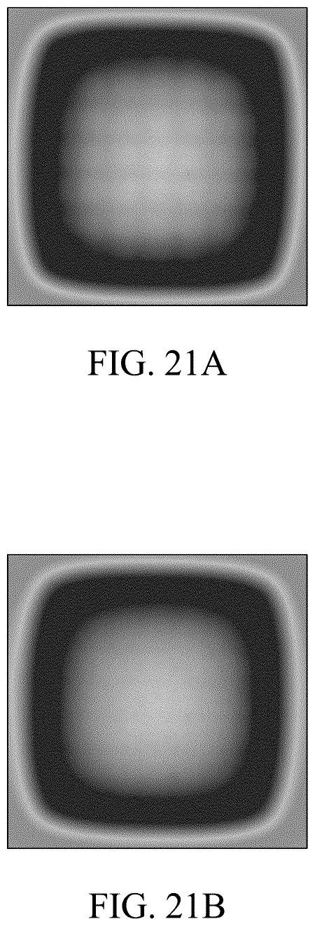

Next, please refer to FIG. 21A and FIG. 21B. FIG. 21A is an image of the optical structure applied to an actual module according to a comparative example. FIG. 21B is an image of the optical structure applied to an actual module according to an example of the present disclosure. Specifically, FIG. 21A shows the image of a plurality of optical structures of Comparative Example 1 applied to a backlight module, and FIG. 21B shows the image of a plurality of optical structures of Example 1 applied to a backlight module. As shown in FIG. 21A and FIG. 21B, compared with the optical structure of Comparative Example 1, the backlight module formed by the optical structures of Example 1 has a larger light spot, and the module quality is more uniform.

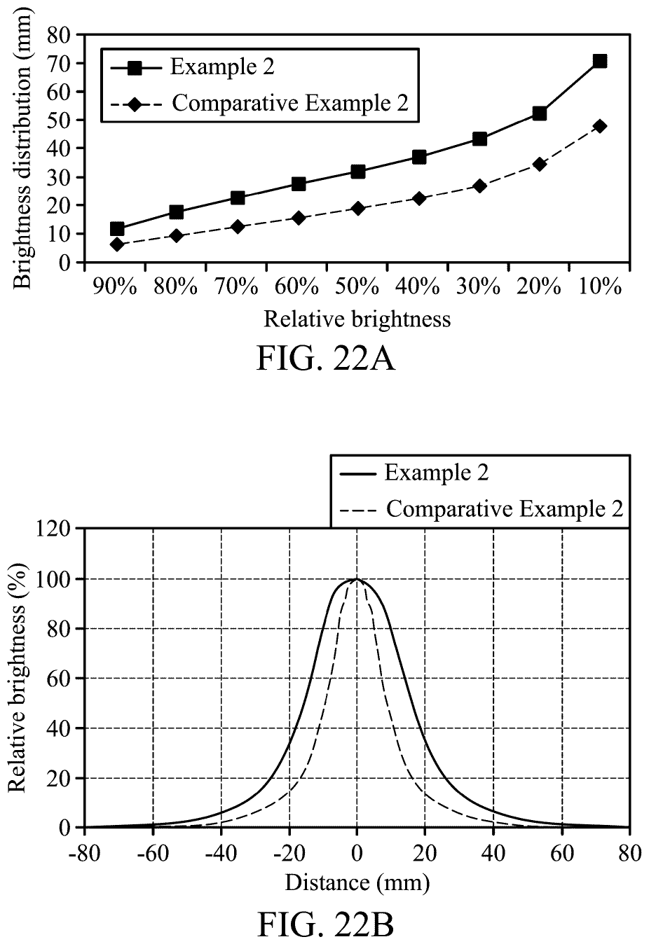

Next, please refer to FIG. 22A and FIG. 22B. FIG. 22A shows a light pattern simulation diagram of the optical structures according to a comparative example (Comparative Example 2) and an example (Example 2) of the present disclosure. FIG. 22B is a comparison result of the brightness distribution of the optical structures according to a comparative example (Comparative Example 2) and an example of the present disclosure (Example 2). Specifically, Comparative Example 2 is the light pattern simulation result of a conventional optical structure (for example, a white LED with a rectangular wavelength conversion layer covering the light-emitting element on the bracket). The optical structure of Example 2 is as shown in FIG. 6A. As shown in FIG. 22A, compared with Comparative Example 2, the overall brightness of the optical structure of Example 2 is higher, and it has a larger light pattern and light spot. As shown in FIG. 22B, compared with Comparative Example 2, the brightness distribution of the optical structure of Example 2 of the present disclosure is more uniform.

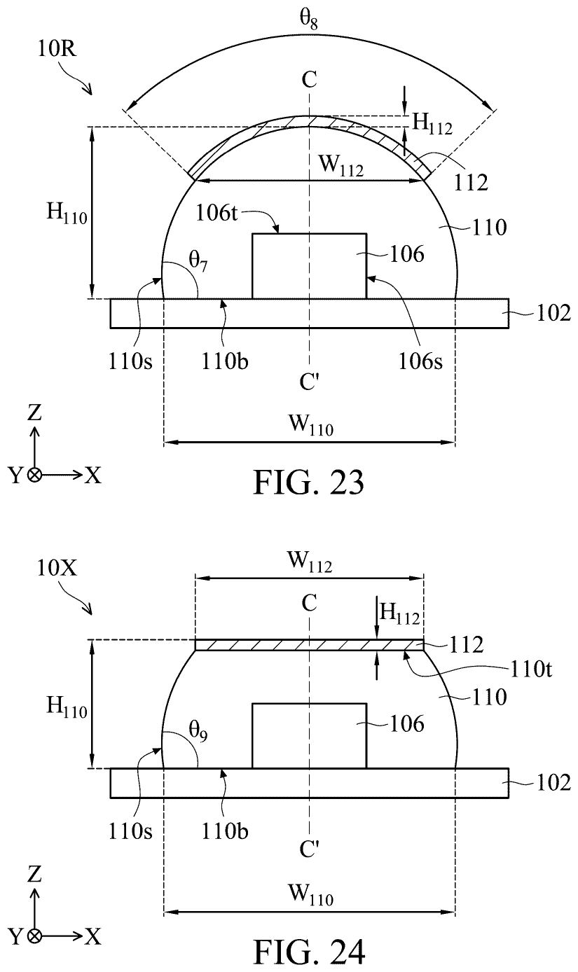

Please refer to FIG. 23, which is a cross-sectional diagram of an optical structure 10R in accordance with some other embodiments of the present disclosure. As shown in FIG. 23, the optical structure 10R includes a substrate 102, a light-emitting element 106, a glue layer 110, and a light-adjusting element 112. The optical structure 10R may not have a wavelength conversion layer. The light-emitting element 106 may be disposed on the substrate 102. The glue layer 110 may cover the light-emitting element 106. Specifically, the glue layer 110 may be in contact with the top surface 106t and the side surface 106s of the light-emitting element 106. Furthermore, the light-adjusting element 112 may be disposed on the glue layer 110, and the light-adjusting element 112 may be in contact with the glue layer 110.

In this embodiment, the light-adjusting element 112 is conformally disposed above the glue layer 110, and the glue layer 110 may have a curved surface. The glue layer 110 may be in the shape of a hemisphere, but the present disclosure is not limited thereto. In this embodiment, the ratio of the height H₁₁₀ of the glue layer 110 to the width W₁₁₀ of the glue layer 110 may be greater than 0 and less than or equal to 0.5 (i.e., 0<H₁₁₀/W₁₁₀≤0.5), for example, 0.05, 0.1, 0.15, 0.2, 0.25, 0.3, 0.35, 0.4 or 0.45, but it is not limited thereto. Furthermore, there is an included angle θ₇ between the side surface 110s and the bottom surface 110b of the glue layer 110. The included angle θ₇ between the side surface 110s and the bottom surface 110b of the glue layer 110 may be less than or equal to 90 degrees (e.g., the included angle θ₇≤90 degrees). In this embodiment, the side surface 110s of the glue layer 110 is curved. In detail, according to the embodiments of the present disclosure, the aforementioned included angle θ₇ refers to the included angle between the tangent line of the side surface (curved surface) 110s and the bottom surface 110b of the glue layer 110.

Moreover, the light-adjusting element 112 may have a height H₁₁₂. In this embodiment, the height H₁₁₂ of the light-adjusting element 112 may be between 10 μm and 300 μm, or between 50 μm and 250 μm, for example, 100 μm, 150 μm or 200 μm, but it is not limited thereto. In addition, as shown in FIG. 23, the light-adjusting element 112 may partially cover the glue layer 110, and the angle θ₈ of the light-adjusting element 112 covering the glue layer 110 may be less than or equal to 135 degrees (i.e. the angle θ₈≤135 degrees).

It should be noted that the height of the light-adjusting element 112 and the area of the light-adjusting element 112 covering the glue layer 110 will affect the light pattern of the light-emitting element 106. Specifically, when the area of the light-adjusting element 112 covering the glue layer 110 is too small, the emission angle may be reduced; conversely, when the area of the glue layer 110 covering the light-adjusting element 112 is too large (for example, the angle θ₈>135 degrees), the luminous flux may be reduced, thereby affecting the luminous efficiency of the light-emitting element 106.

In this embodiment, the ratio of the width W₁₁₂ of the light-adjusting element 112 to the width W₁₁₀ of the glue layer 110 is greater than 0 and less than 1. In this embodiment, the refractive index of the glue layer 110 is different from the refractive index of the light-adjusting element 112, and the refractive index of the light-adjusting element 112 may be smaller than the refractive index of the glue layer 110. Furthermore, the optical structure 10R may be a symmetrical structure, for example, having a central axis C-C′. The elements of the optical structure 10R can take the central axis C-C′ as the symmetry axis, and have any suitable shape according to needs. In some embodiments, the optical structure 10R may include the bracket 104.

Next, please refer to FIG. 24, which is a cross-sectional diagram of an optical structure 10X in accordance with some other embodiments of the present disclosure. The optical structure 10X is substantially similar to the optical structure 10R. Compared with the optical structure 10R, the glue layer 110 of the optical structure 10X is non-spherical, such as non-hemispherical. In detail, the top surface 110t of the glue layer 110 of the optical structure 10X may be substantially planar, and the light-adjusting element 112 may be disposed on the top surface 110t of the glue layer 110, so the light-adjusting element 112 may have a flat-plate shape.

In this embodiment, the ratio of the height H₁₁₀ of the glue layer 110 to the width W₁₁₀ of the glue layer 110 may be greater than 0 and less than or equal to 1 (i.e., 0<H₁₁₀/W₁₁₀≤1), for example, 0.1, 0.2, 0.3, 0.4, 0.5, 0.6, 0.7, 0.8 or 0.9, but it is not limited thereto. Furthermore, there is an included angle θ₉ between the side surface 110s and the bottom surface 110b of the glue layer 110. The included angle θ₉ between the side surface 110s and the bottom surface 110b of the glue layer 110 may be less than or equal to 90 degrees (i.e., the included angle θ₉≤90 degrees). In this embodiment, the side surface 110s of the glue layer 110 is curved. In detail, in accordance with the embodiments of the present disclosure, the aforementioned included angle θ₉ refers to the included angle between the tangent line of the side surface (curved surface) 110s and the bottom surface 110b of the glue layer 110.

Furthermore, the light-adjusting element 112 has a height H₁₁₂, and the height H₁₁₂ of the light-adjusting element 112 may be between 10 μm and 300 μm, or between 50 μm and 250 μm, for example, 100 μm, 150 μm or 200 μm, but it is not limited thereto. In addition, as shown in FIG. 24, the light-adjusting element 112 partially covers the glue layer 110, and the ratio of the width W₁₁₂ of the light-adjusting element 112 to the width W₁₁₀ of the glue layer 110 may be greater than 0 and less than or equal to 1 (i.e., 0<W₁₁₂/W₁₁₀≤1).

It should be noted that the height of the light-adjusting element 112 and the area of the light-adjusting element 112 covering the glue layer 110 will affect the light pattern of the light-emitting element 106. Specifically, when the area of the light-adjusting element 112 covering the glue layer 110 is too small, the light-emitting angle may be too small; conversely, when the area of the light-adjusting element 112 covering the glue layer 110 is too large (for example, W₁₁₂/W₁₁₀>1), the luminous flux may be reduced, thereby affecting the luminous efficiency of the light-emitting element 106.

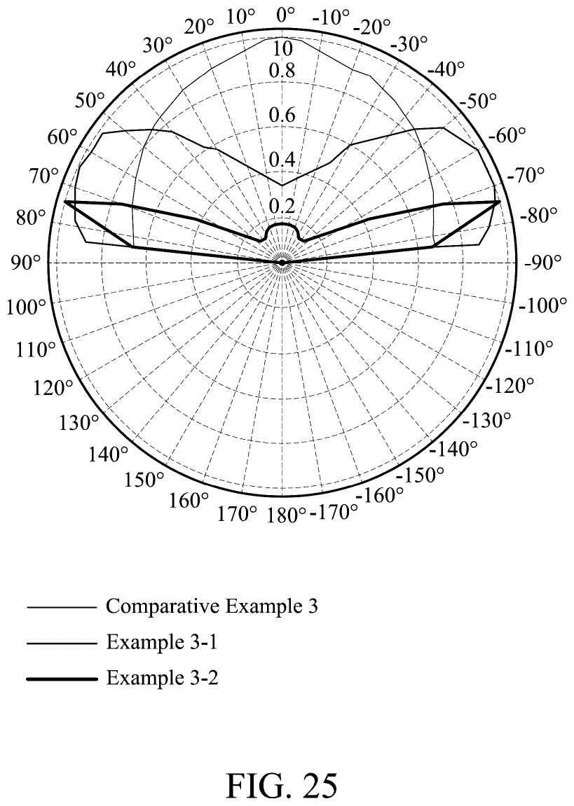

Similarly, in this embodiment, the refractive index of the glue layer 110 is different from the refractive index of the light-adjusting element 112, and the refractive index of the light-adjusting element 112 may be smaller than the refractive index of the glue layer 110. Furthermore, the optical structure 10X may be a symmetrical structure, for example, having a central axis C-C′. The elements of the optical structure 10X can take the central axis C-C′ as the symmetry axis, and have any suitable shape according to needs. In some embodiments, the optical structure 10X may include a bracket 104. Next, please refer to FIG. 25, which is a comparison result of the brightness distribution of optical structures according to a comparative example (Comparative Example 3) and some examples of the present disclosure (Example 3-1, Example 3-2). Specifically, Comparative Example 3 is the brightness distribution result of a conventional optical structure (for example, a hemispherical white LED without a light-adjusting element). Example 3-1 corresponds to the optical structure shown in FIG. 23. Example 3-2 corresponds to the optical structure shown in FIG. 24. As shown in FIG. 25, compared with Comparative Example 3, the optical structures of Examples 3-1 and 3-2 have a larger light-emitting angle and have better brightness uniformity when applied to backlight modules.

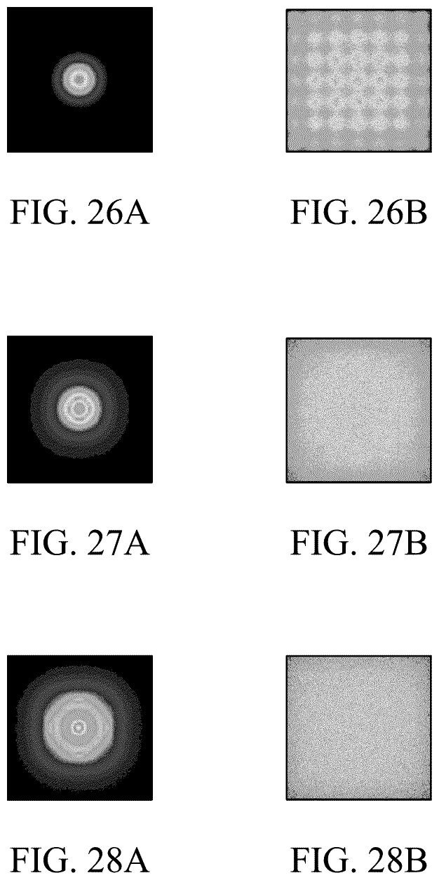

Next, please refer to FIG. 26A, FIG. 26B, FIG. 27A, FIG. 27B, FIG. 28A and FIG. 28B. FIG. 26A and FIG. 26B are respectively an image of the light spot of an optical structure and an image of the optical structure applied to the actual module according to a comparative example (Comparative Example 3). FIG. 27A and FIG. 27B are respectively an image of the light spot of an optical structure and an image of the optical structure applied to the actual module in accordance with an example of the present disclosure (Example 3-1). FIG. 28A and FIG. 28B are respectively an image of the light spot of an optical structure and an image of the optical structure applied to the actual module in accordance with another example of the present disclosure (Example 3-2).

According to the foregoing results, it can be seen that compared with Comparative Example 3, the optical structures of Example 3-1 and Example 3-2 have larger light spots and more uniform brightness distribution. Furthermore, compared with the optical structure of Comparative Example 3, the backlight module formed by the optical structures of Example 3-1 and Example 3-2 have a larger light spot, and the module quality is more uniform.

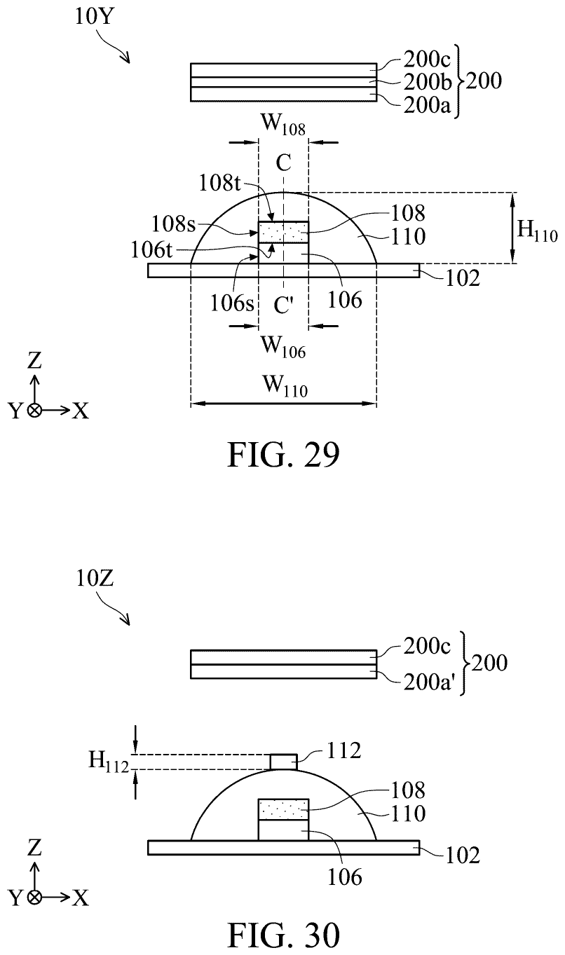

Next, please refer to FIG. 29, which is a cross-sectional diagram of an optical structure 10Y in accordance with some other embodiments of the present disclosure. As shown in FIG. 29, the optical structure 10Y may include a substrate 102, a light-emitting element 106, a wavelength conversion layer 108, a glue layer 110, and an optical component 200. The light-emitting element 106 may be disposed on the substrate 102. The wavelength conversion layer 108 may be disposed on the light-emitting element 106, and the wavelength conversion layer 108 may be in contact with the top surface 106t of the light-emitting element 106. The glue layer 110 may cover the wavelength conversion layer 108. Specifically, the glue layer 110 may be in contact with the top surface 108t and the side surface 108s of the wavelength conversion layer 108. The glue layer 110 may be in contact with the side surface 106s of the light-emitting element 106. Furthermore, the optical component 200 may be disposed corresponding to the glue layer 110; for example, the optical component 200 may overlap the glue layer 110.

In accordance with some embodiments, the optical component 200 may include a diffusion film 200a, a wavelength conversion film 200b disposed on the diffusion film 200a, and a brightness enhancement film 200c disposed on the wavelength conversion film 200b. In accordance with some embodiments, the wavelength conversion film 200b may be a quantum dot film or a phosphor layer. It should be noted that in the comparative example where a reflective film is disposed above the light-emitting element (for example, Comparative Example 4 described below, which has a similar structure to FIG. 29 but the wavelength conversion layer 108 is replaced by a reflective layer), when the light-emitting element 106 emits blue light, since the light is converted by the wavelength conversion film only once, it is easy to cause uneven color conversion, causing parts of the displayed image to be bluish and some to be yellow, resulting in blue halo and yellow halo phenomena. In accordance with the embodiments of the present disclosure, after the wavelength conversion layer 108 on the light-emitting element 106 performs the first wavelength conversion, the wavelength conversion film 200b disposed above the glue layer 110 performs the second wavelength conversion. In this way, in addition to maintaining a relatively large light-emitting angle, it can also effectively improve the blue halo and yellow halo phenomena when used in modules.

Furthermore, in this embodiment, the refractive index of the wavelength conversion layer 108 is different from the refractive index of the glue layer 110, and the refractive index of the wavelength conversion layer 108 may be greater than the refractive index of the glue layer 110. In other words, the ratio of the refractive index of the glue layer 110 to the refractive index of the wavelength conversion layer 108 is less than 1. This configuration can enhance the luminous efficiency of the light-emitting element 106 and improve the light pattern of the optical structure.

In this embodiment, the glue layer 110 may have a curved surface. The glue layer 110 may be in the shape of a hemisphere, but the present disclosure is not limited thereto. In this embodiment, the ratio of the height H₁₁₀ of the glue layer 110 to the width W₁₁₀ of the glue layer 110 may be greater than 0 and less than or equal to 0.5 (i.e., 0<H₁₁₀/W₁₁₀≤0.5), for example, 0.05, 0.1, 0.15, 0.2, 0.25, 0.3, 0.35, 0.4 or 0.45, but it is not limited thereto. Furthermore, in this embodiment, the ratio of the width W₁₀₈ of the wavelength conversion layer 108 to the width W 106 of the light-emitting element 106 may be between 0.5 and 2 (i.e., 0.5≤W₁₀₈/W₁₀₆≤2), for example, 0.6, 0.7, 0.8, 0.9, 1, 1.1, 1.2, 1.3, 1.4, 1.5, 1.6, 1.7, 1.8 or 1.9, but it is not limited thereto.

In addition, the optical structure 10Y may be a symmetrical structure, for example, having a central axis C-C′. The elements of the optical structure 10Y can take the central axis C-C′ as the symmetry axis, and have any suitable shape according to needs.

In accordance with some embodiments, the light-emitting element 106 is a light-emitting diode that emits blue light, and the wavelength conversion layer 108 includes yellow phosphor, so the optical structure 10Y can emit white light, but the present disclosure is not limited thereto. In accordance with some other embodiments, the light-emitting element 106 is a light-emitting diode that emits blue light, but does not have the wavelength conversion layer 108, so the optical structure 10Y can emit blue light.

Next, please refer to FIG. 30, which is a cross-sectional diagram of an optical structure 10Z in accordance with some other embodiments of the present disclosure. The optical structure 10Z is substantially similar to the optical structure 10Y. Compared with the optical structure 10Y, the optical component 200 of the optical structure 10Z may include a wavelength conversion diffusion film 200a′ and a brightness enhancement film 200c disposed on the wavelength conversion diffusion film 200a′. Similarly, after the wavelength conversion layer 108 on the light-emitting element 106 performs the first wavelength conversion, the wavelength conversion diffusion film 200a′ disposed above the glue layer 110 performs the second wavelength conversion. In this way, in addition to maintaining a relatively large light-emitting angle, it can also effectively improve the blue halo and yellow halo phenomena when used in modules.

Moreover, compared with the optical structure 10Y, the optical structure 10Z further includes a light-adjusting element 112. The light-adjusting element 112 may be disposed on the glue layer 110 and between the glue layer 110 and the optical component 200. The light-adjusting element 112 has a height H₁₁₂, and the height H₁₁₂ of the light-adjusting element 112 may be between 10 μm and 300 μm, or between 50 μm and 250 μm, for example, 100 μm, 150 μm, or 200 μm, but it is not limited thereto.

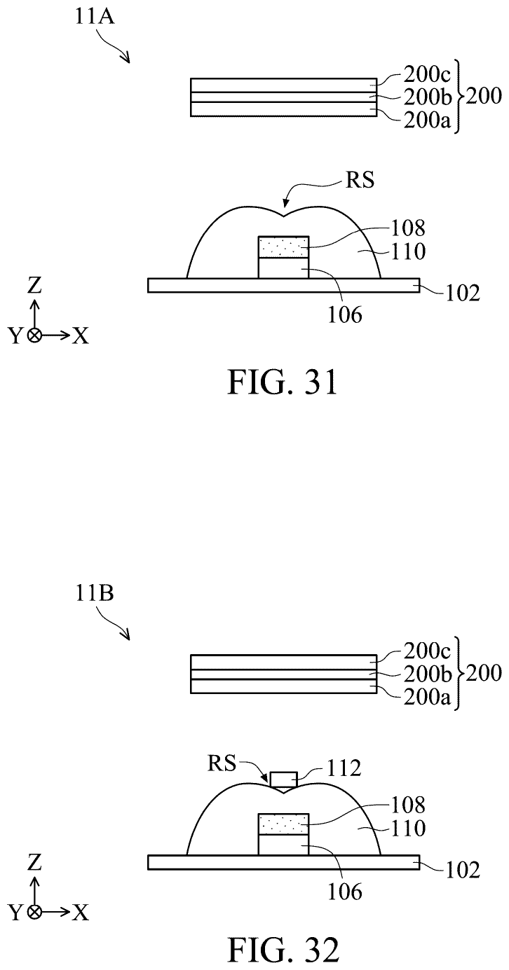

Next, please refer to FIG. 31, which is a cross-sectional diagram of an optical structure 11A in accordance with some other embodiments of the present disclosure. The optical structure 11A is substantially similar to the optical structure 10Y. Compared with the optical structure 10Y, the glue layer 110 of the optical structure 11A has multiple curved surfaces, such as two protrusions. Furthermore, the glue layer 110 of the optical structure 11A may further have a recess Rs, and the recess Rs may be disposed on the top of the glue layer 110.

Next, please refer to FIG. 32, which is a cross-sectional diagram of an optical structure 11B in accordance with some other embodiments of the present disclosure. The optical structure 11B is substantially similar to the optical structure 11A. Compared with the optical structure 11A, the optical structure 11B further includes a light-adjusting element 112, and the light-adjusting element 112 may be disposed on the glue layer 110 and between the glue layer 110 and the optical component 200. Furthermore, the light-adjusting element 112 may be disposed above the recess Rs and overlap with the recess Rs.

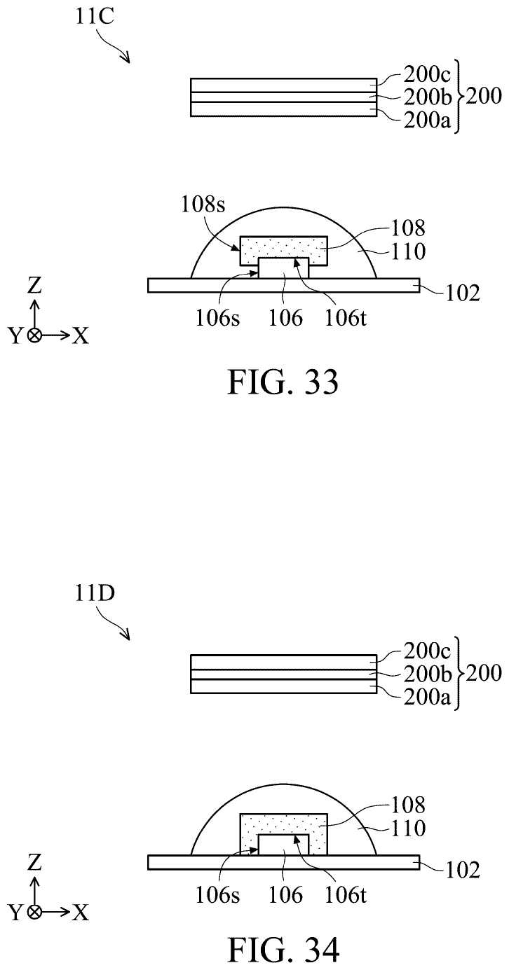

Next, please refer to FIG. 33, which is a cross-sectional diagram of an optical structure 11C in accordance with some other embodiments of the present disclosure. The optical structure 11C is substantially similar to the optical structure 10Y. Compared with the optical structure 10Y, the side surface 108s of wavelength conversion layer 108 of the optical structure 11C and the side surface 106s of the light-emitting element 106 are non-coplanar. In detail, the side surface 108s of the wavelength conversion layer 108 of the optical structure 11C may protrude from the side surface 106s of the light-emitting element 106, and the wavelength conversion layer 108 may be in contact with the side surface 106s and the top surface 106t of the light-emitting element 106. The wavelength conversion layer 108 may partially cover the side surface 106s of the light-emitting element 106.

Next, please refer to FIG. 34, which is a cross-sectional diagram of an optical structure 11D in accordance with some other embodiments of the present disclosure. The optical structure 11D is substantially similar to the optical structure 10Y. Compared with the optical structure 10Y, the wavelength conversion layer 108 of the optical structure 11D may be in contact with the side surface 106s and the top surface 106t of the light-emitting element 106. The wavelength conversion layer 108 may entirely cover the side surface 106s and the top surface 106t of the light-emitting element 106.

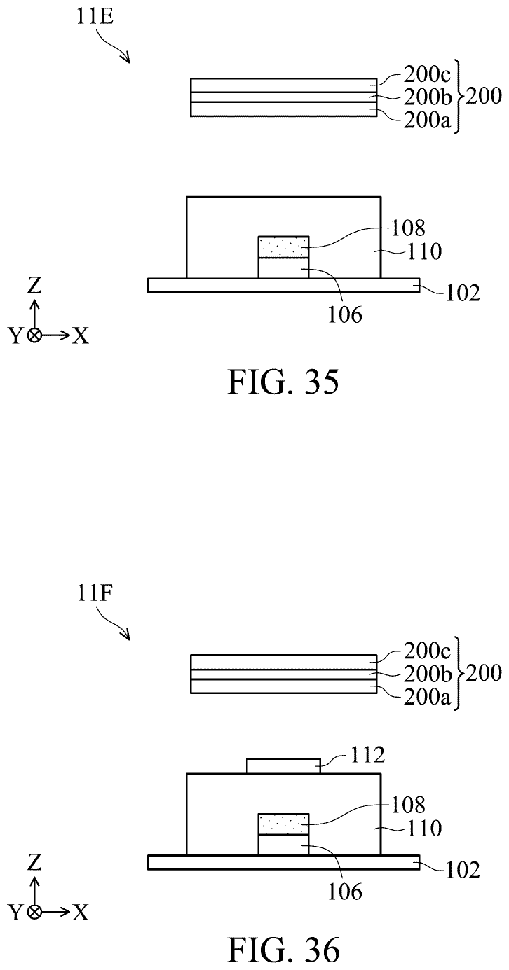

Next, please refer to FIG. 35, which is a cross-sectional diagram of an optical structure 11E in accordance with some other embodiments of the present disclosure. The optical structure 11E is substantially similar to the optical structure 10Y. Compared with the optical structure 10Y, the glue layer 110 of the optical structure 11E has a right-angled profile, and the glue layer 110 may be a rectangular parallelepiped or a cube.

Next, please refer to FIG. 36, which is a cross-sectional diagram of an optical structure 11F in accordance with some other embodiments of the present disclosure. The optical structure 11F is substantially similar to the optical structure 11E. Compared with the optical structure 11E, the optical structure 11F further includes a light-adjusting element 112, and the light-adjusting element 112 may be disposed on the glue layer 110 and between the glue layer 110 and the optical component 200.

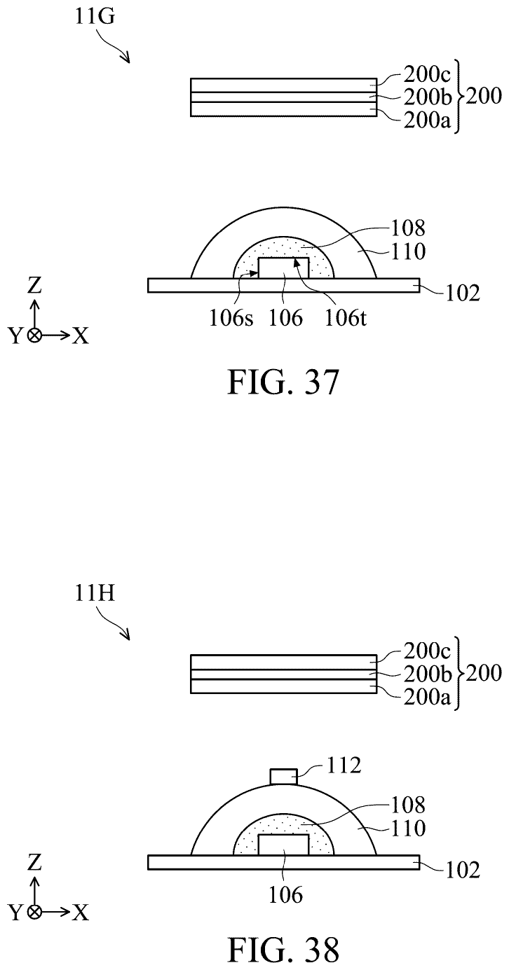

Next, please refer to FIG. 37, which is a cross-sectional diagram of an optical structure 11G in accordance with some other embodiments of the present disclosure. The optical structure 11G is substantially similar to the optical structure 10Y. Compared with the optical structure 10Y, the wavelength conversion layer 108 of the optical structure 11G has a curved surface, and the wavelength conversion layer 108 may be in the shape of a hemisphere. Furthermore, the wavelength conversion layer 108 of the optical structure 11G may be in contact with the side surface 106s and the top surface 106t of the light-emitting element 106, and the wavelength conversion layer 108 may entirely cover the side surface 106s and the top surface 106t of the light-emitting element 106.

Next, please refer to FIG. 38, which is a cross-sectional diagram of an optical structure 11H in accordance with some other embodiments of the present disclosure. The optical structure 11H is substantially similar to the optical structure 11G. Compared with the optical structure 11G, the optical structure 11H further includes a light-adjusting element 112. The light-adjusting element 112 may be disposed on the glue layer 110 and between the glue layer 110 and the optical component 200.

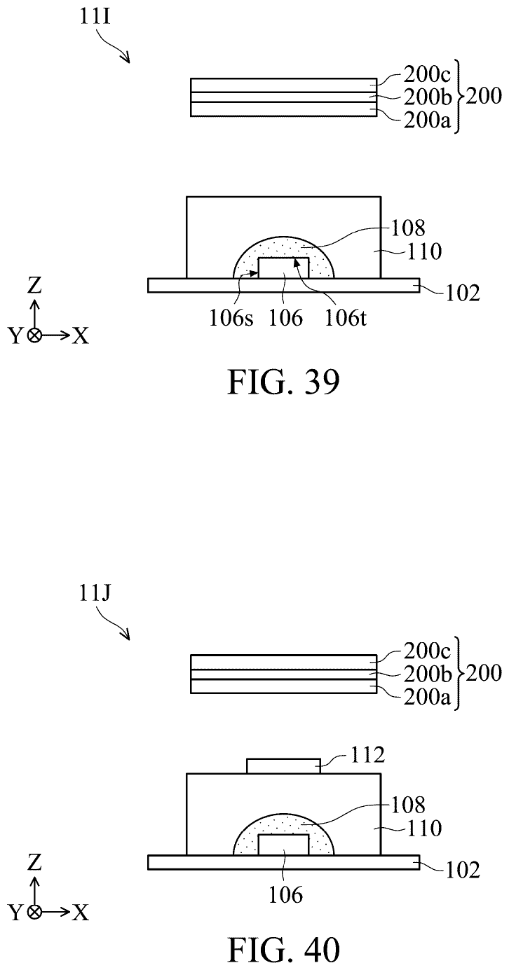

Next, please refer to FIG. 39, which is a cross-sectional diagram of an optical structure 11I in accordance with some other embodiments of the present disclosure. The optical structure 11I is substantially similar to the optical structure 10Y. Compared with the optical structure 10Y, the wavelength conversion layer 108 of the optical structure 11I has a curved surface, and the wavelength conversion layer 108 may be in the shape of a hemisphere. The wavelength conversion layer 108 of the optical structure 11I may be in contact with the side surface 106s and the top surface 106t of the light-emitting element 106, and the wavelength conversion layer 108 may entirely cover the side surface 106s and the top surface 106t of the light-emitting element 106. Furthermore, the glue layer 110 of the optical structure 11I has a right-angled profile, and the glue layer 110 may be a rectangular parallelepiped or a cube.

Next, please refer to FIG. 40, which is a cross-sectional diagram of an optical structure 11J in accordance with some other embodiments of the present disclosure. The optical structure 11J is substantially similar to the optical structure 11I. Compared with the optical structure 11I, the optical structure 11J further includes a light-adjusting element 112. The light-adjusting element 112 may be disposed on the glue layer 110 and between the glue layer 110 and the optical component 200.

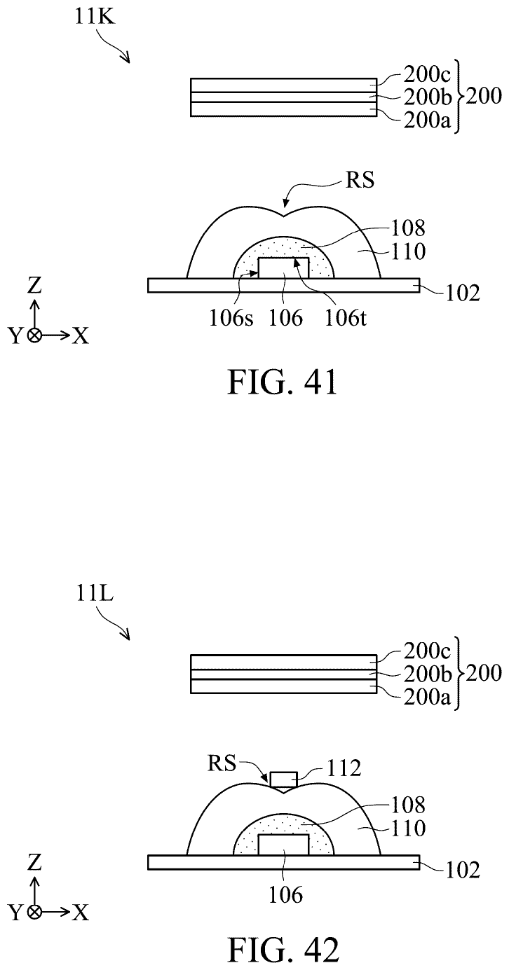

Next, please refer to FIG. 41, which is a cross-sectional diagram of an optical structure 11K in accordance with some other embodiments of the present disclosure. The optical structure 11K is substantially similar to the optical structure 10Y. Compared with the optical structure 10Y, the wavelength conversion layer 108 of the optical structure 11K has a curved surface, and the wavelength conversion layer 108 may be in the shape of a hemisphere. The wavelength conversion layer 108 of the optical structure 11K may be in contact with the side surface 106s and the top surface 106t of the light-emitting element 106, and the wavelength conversion layer 108 may entirely cover the side surface 106s and the top surface 106t of the light-emitting element 106. Furthermore, the glue layer 110 of the optical structure 11K also has curved surfaces, such as two protrusions. In addition, the glue layer 110 of the optical structure 11A further has a recess Rs, and the recess Rs may be disposed on the top of the glue layer 110.

Next, please refer to FIG. 42, which is a cross-sectional diagram of an optical structure 11L in accordance with some other embodiments of the present disclosure. The optical structure 11L is substantially similar to the optical structure 11K. Compared with the optical structure 11K, the optical structure 11L further includes a light-adjusting element 112. The light-adjusting element 112 may be disposed on the glue layer 110 and between the glue layer 110 and the optical component 200. Furthermore, the light-adjusting element 112 may be disposed above the recess Rs and overlap with the recess Rs.

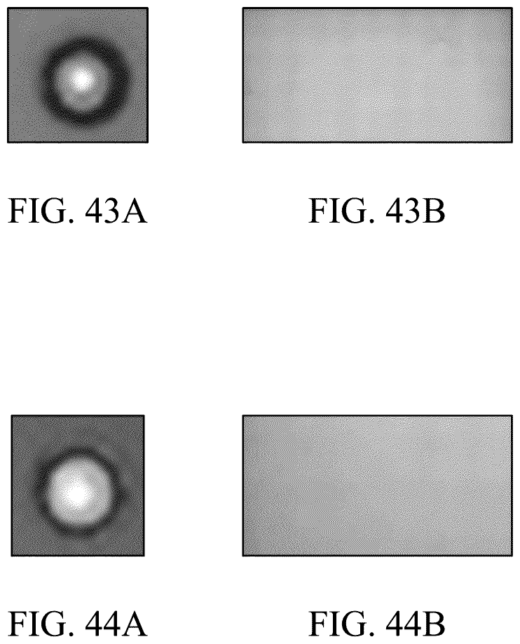

Please refer to FIG. 43A, FIG. 43B, FIG. 44A and FIG. 44B. FIG. 43A and FIG. 43B are respectively an image of the light spot of an optical structure and an image of the optical structure applied to the actual module according to a comparative example (Comparative Example 4). FIG. 44A and FIG. 44B are respectively an image of the light spot of an optical structure and an image of the optical structure applied to the actual module in accordance with an example (Example 4) of the present disclosure. Specifically, Comparative Example 4 is the result of a conventional optical structure (for example, a semispherical white LED with a reflective film disposed above the light-emitting element), and Example 4 is the result corresponding to the optical structure shown in FIG. 29.

From the above results, it can be seen that compared with Comparative Example 4, the blue halo of the optical structure of Example 4 is smaller, and the blue halo and yellow halo phenomena when applied to the module are also significantly improved, and the module quality is more uniform.

Based on the above, according to the embodiments of the present disclosure, the optical structure can be applied to the backlight module. The following description provides some aspects of the optical structure when applied to the backlight module in accordance with some embodiments. It should be understood that the figures do not illustrate how all the aforementioned optical structures are applied to the backlight module, but the optical structures of the embodiments of the present disclosure can all be configured in a similar manner.

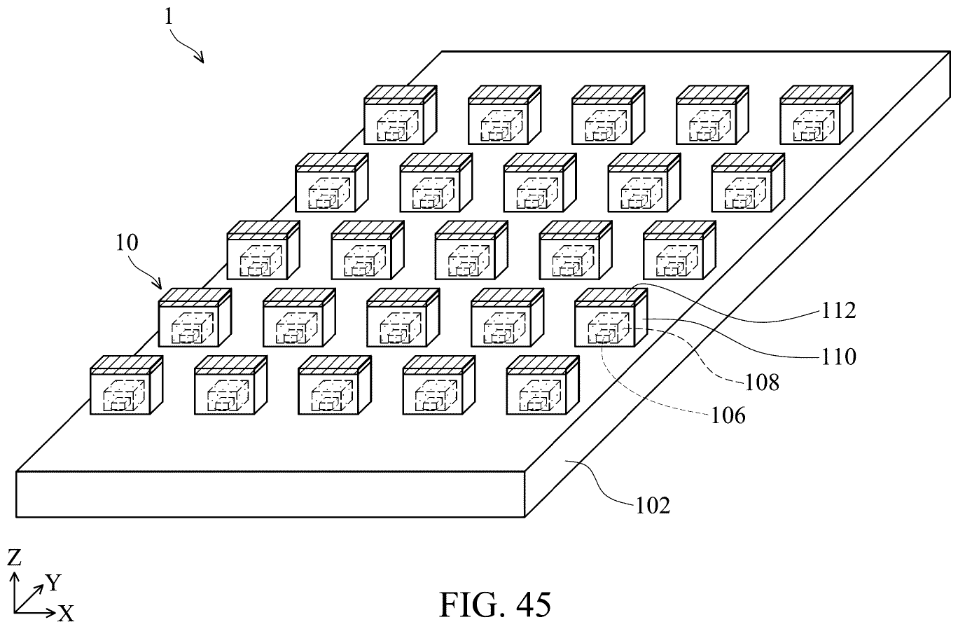

Please refer to FIG. 45, which is a schematic diagram of a backlight module 1 in accordance with some embodiments of the present disclosure. As shown in FIG. 45, the backlight module 1 may include a substrate 102 and a plurality of optical structures 10 disposed on the substrate 102. In this embodiment, the optical structure 10 may be the optical structure 10A shown in FIG. 1A. The optical structures 10 may be arranged in an array, for example, arranged with a first pitch (not labeled) in the X direction, and arranged with a second pitch (not labeled) in the Y direction. The first pitch may be the same as or different from the second pitch. Furthermore, in this embodiment, the light-emitting element 106 is a light-emitting diode that emits blue light, the wavelength conversion layer 108 includes yellow phosphor, and the optical structure 10 can emit white light. Moreover, the optical component 200 (not illustrated) may be further disposed above the optical structure 10. The optical component 200 may include a diffusion film 200a (not illustrated) and a brightness enhancement film 200c (not illustrated) disposed on the diffusion film 200a, but it is not limited thereto.

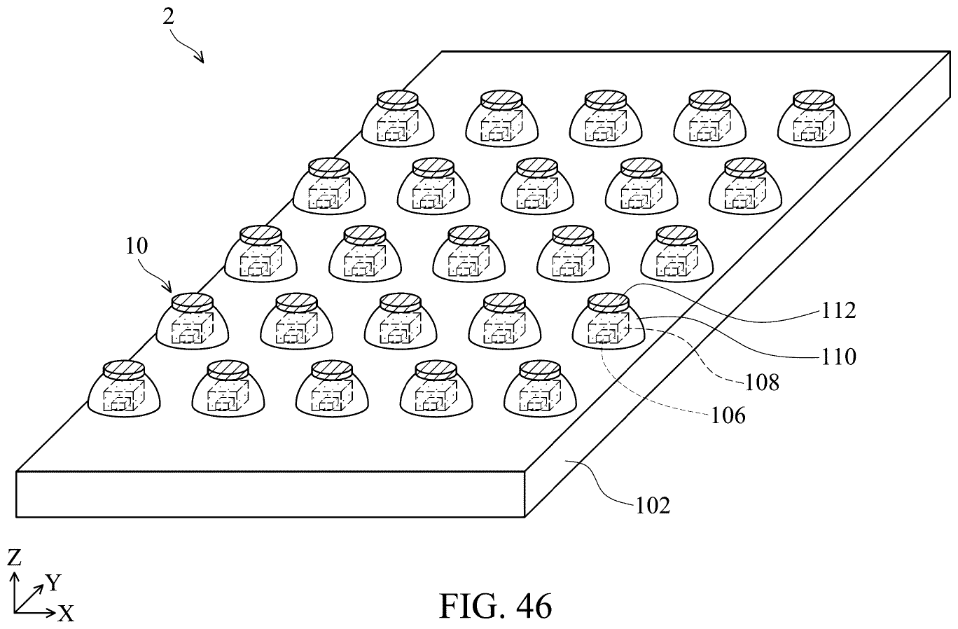

Next, please refer to FIG. 46, which is a schematic diagram of a backlight module 2 in accordance with some other embodiments of the present disclosure. As shown in FIG. 46, the backlight module 2 may include a substrate 102 and a plurality of optical structures 10 disposed on the substrate 102. In this embodiment, the optical structure 10 has an optical structure 10C, as shown in FIG. 3A, but does not have the bracket 104. Similarly, the optical structures 10 may be arranged in an array, for example, with a first pitch (not labeled) in the X direction and a second pitch (not labeled) in the Y direction. The first pitch may be the same as or different from the second pitch. Furthermore, in this embodiment, the light-emitting element 106 is a light-emitting diode that emits blue light, the wavelength conversion layer 108 includes yellow phosphor, and the optical structure 10 can emit white light. Moreover, the optical component 200 (not illustrated) may be further disposed above the optical structure 10. The optical component 200 may include a diffusion film 200a (not illustrated) and a brightness enhancement film 200c (not illustrated) disposed on the diffusion film 200a, but it is not limited thereto.

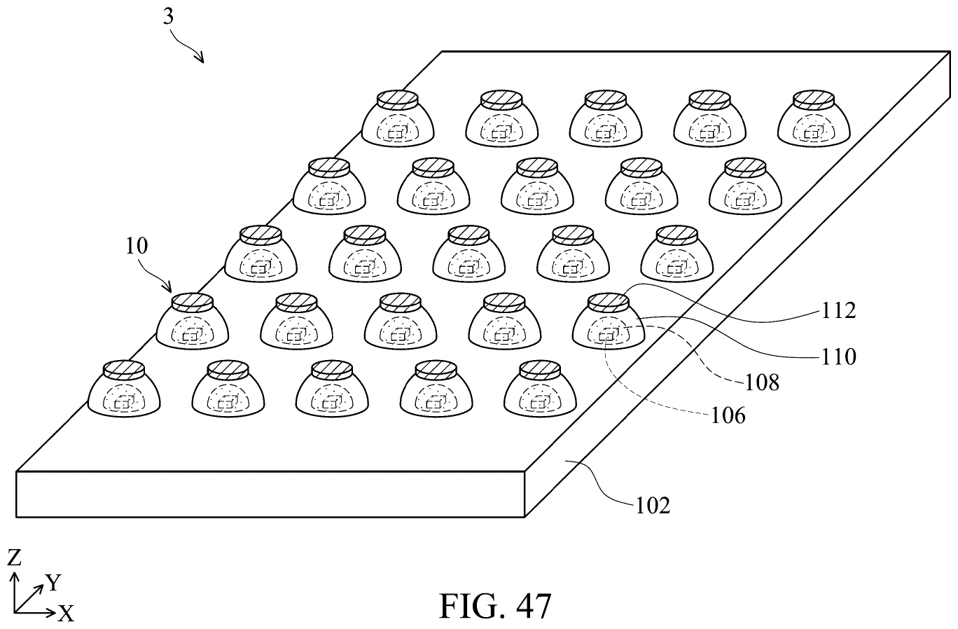

Next, please refer to FIG. 47, which is a schematic diagram of a backlight module 3 in accordance with some other embodiments of the present disclosure. As shown in FIG. 47, the backlight module 3 may include a substrate 102 and a plurality of optical structures 10 disposed on the substrate 102. In this embodiment, the optical structure 10 has an optical structure 10I as shown in FIG. 9, but does not have the bracket 104. Similarly, the optical structures 10 may be arranged in an array, for example, with a first pitch (not labeled) in the X direction and a second pitch (not labeled) in the Y direction. The first pitch may be the same as or different from the second pitch. Furthermore, in this embodiment, the light-emitting element 106 is a light-emitting diode that emits blue light, the wavelength conversion layer 108 includes yellow phosphor, and the optical structure 10 can emit white light. Moreover, the optical component 200 (not illustrated) may be further disposed above the optical structure 10. The optical component 200 may include a diffusion film 200a (not illustrated) and a brightness enhancement film 200c (not illustrated) disposed on the diffusion film 200a, but it is not limited thereto.

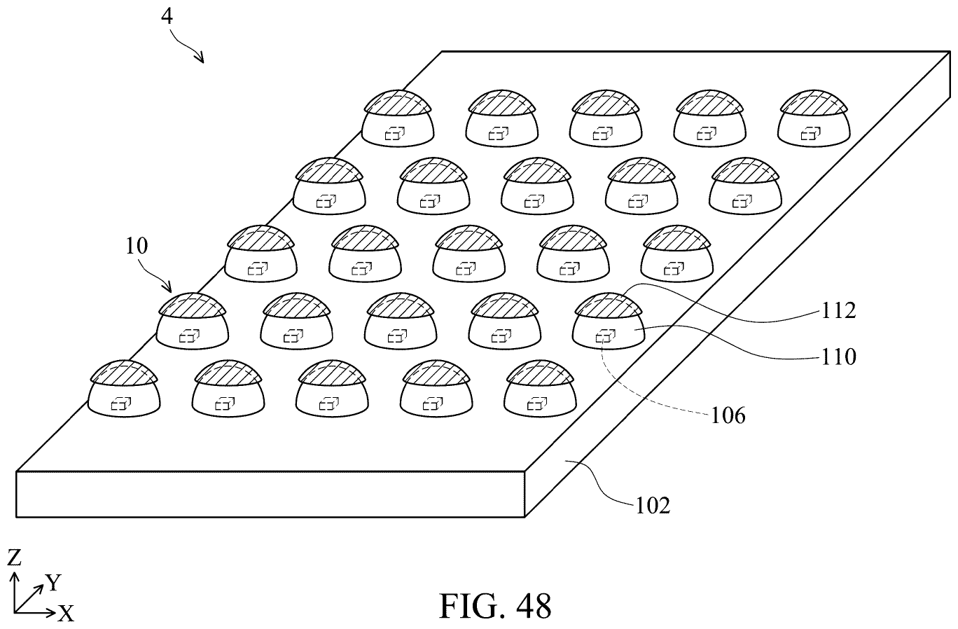

Next, please refer to FIG. 48, which is a schematic diagram of a backlight module 4 in accordance with some other embodiments of the present disclosure. As shown in FIG. 48, the backlight module 4 may include a substrate 102 and a plurality of optical structures 10 disposed on the substrate 102. In this embodiment, the optical structure 10 has an optical structure 10R as shown in FIG. 23. Similarly, the optical structures 10 may be arranged in an array, for example, with a first pitch (not labeled) in the X direction and a second pitch (not labeled) in the Y direction. The first pitch may be the same as or different from the second pitch. Furthermore, in this embodiment, the light-emitting element 106 is a light-emitting diode that emits blue light, and the optical structure 10 can emit blue light. Moreover, the optical component 200 (not illustrated) may be further disposed above the optical structure 10. The optical component 200 may include a diffusion film 200a (not illustrated), a wavelength conversion film 200b (not illustrated) disposed on the diffusion film 200a, and a brightness enhancement film 200c (not illustrated) disposed on the wavelength conversion film 200b, but it is not limited thereto. In some embodiments, the wavelength conversion film 200b may be a quantum dot film. In some embodiments, the wavelength conversion film 200b may be a yellow quantum dot film. In some embodiments, the wavelength conversion film 200b may be red and green quantum dot films. In some embodiments, the wavelength conversion film 200b may be yellow phosphor. For example, the yellow phosphor may include yttrium aluminum garnet (YAG) phosphor. In some embodiments, the wavelength conversion film 200b may include green phosphor and red phosphor. For example, the wavelength conversion film 200b may include green Sialon phosphor and red K₂SiF₆:Mn⁴⁺. In some embodiments, the wavelength conversion film 200b may include a combination of one green phosphor and two red phosphors. For example, the wavelength conversion film 200b may include a green Sialon phosphor, red K₂SiF₆:Mn⁴⁺, and red (Sr,Ca)AlSiN₃:Eu²⁺.

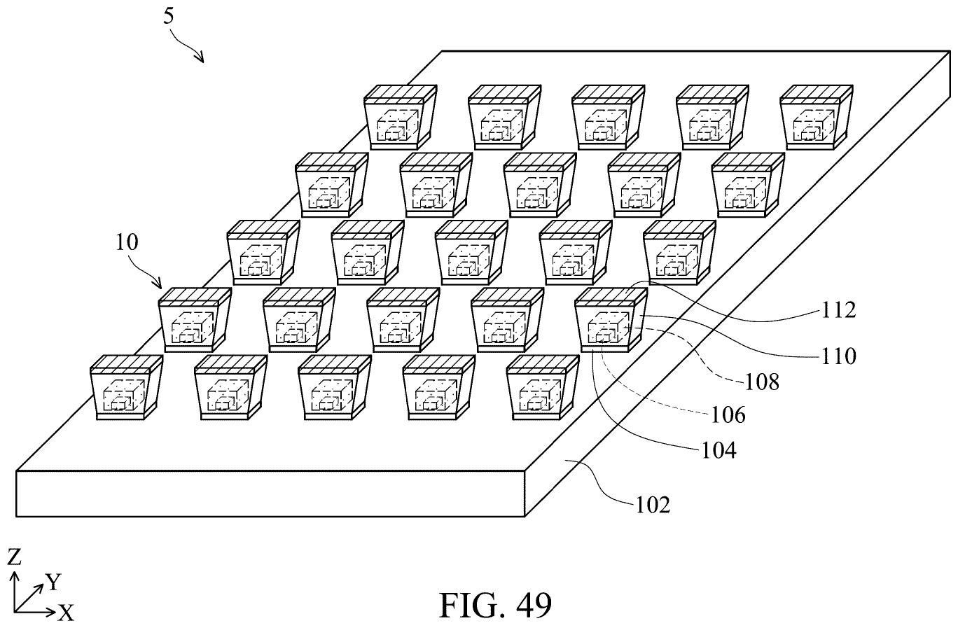

Next, please refer to FIG. 49, which is a schematic diagram of a backlight module 5 in accordance with some other embodiments of the present disclosure. As shown in FIG. 49, the backlight module 5 may include a substrate 102 and a plurality of optical structures 10 disposed on the substrate 102. In this embodiment, the optical structure 10 has an optical structure 10D as shown in FIG. 4A, but further has a bracket 104. Similarly, the optical structures 10 may be arranged in an array, for example, with a first pitch (not labeled) in the X direction and a second pitch (not labeled) in the Y direction. The first pitch may be the same as or different from the second pitch. Furthermore, in this embodiment, the light-emitting element 106 is a light-emitting diode that emits blue light, the wavelength conversion layer 108 includes yellow phosphor, and the optical structure 10 can emit white light. Moreover, the optical component 200 (not illustrated) may be further disposed above the optical structure 10. The optical component 200 may include a diffusion film 200a (not illustrated) and a brightness enhancement film 200c (not illustrated) disposed on the diffusion film 200a, but it is not limited thereto.

To summarize the above, the optical structure provided by the embodiments of the present disclosure includes a wavelength conversion layer and a glue layer configured in a specific size ratio, thereby improving the luminous efficiency and luminous angle of the light-emitting element, and reducing the manufacturing costs when applied to modules. In accordance with some other embodiments of the present disclosure, the optical structure provided can increase the intensity of the lateral light source and improve the reflection effect of the light source. In accordance with still some embodiments of the present disclosure, the optical structure provided includes a light-adjusting layer and a glue layer configured in a specific size ratio, thereby improving the luminous efficiency and luminous angle of the light-emitting element. In accordance with still some embodiments of the present disclosure, the optical structure provided includes an optical component that can additionally perform wavelength conversion, thereby maintaining a large-angled light pattern and effectively improving the blue halo and yellow halo phenomena.

Although some embodiments of the present disclosure and their advantages have been described in detail, it should be understood that various changes, substitutions and alterations can be made herein without departing from the spirit and scope of the present disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An optical structure, comprising:
a substrate;
a light-emitting element disposed on the substrate;
a glue layer covering the light-emitting element; and
a light-adjusting element disposed on the glue layer,
wherein the refractive index of the glue layer is different from the refractive index of the light-adjusting element.

2. The optical structure as claimed in claim 1, further comprising:
a wavelength conversion layer, wherein the wavelength conversion layer covers the light-emitting element, and the refractive index of the wavelength conversion layer is different from the refractive index of the glue layer.

3. The optical structure as claimed in claim 2, wherein the refractive index of the wavelength conversion layer is greater than the refractive index of the glue layer.

4. The optical structure as claimed in claim 3, wherein a ratio of the refractive index of the glue layer to the refractive index of the wavelength conversion layer is less than 1.

5. The optical structure as claimed in claim 2, wherein a ratio of a width of the wavelength conversion layer to a width of the glue layer is greater than 0 and less than or equal to 0.5.

6. The optical structure as claimed in claim 1, wherein the light-adjusting element is partially reflective and partially transmissive.

7. The optical structure as claimed in claim 1, further comprising:
a bracket disposed between the substrate and the light-emitting element.

8. The optical structure as claimed in claim 1, wherein the light-adjusting element has a curved surface.

9. The optical structure as claimed in claim 1, wherein the glue layer has a curved surface.

10. The optical structure as claimed in claim 2, wherein the wavelength conversion layer has a curved surface.

11. The optical structure as claimed in claim 1, wherein a ratio of height to width of the glue layer is greater than 0 and less than or equal to 0.5.

12. The optical structure as claimed in claim 1, wherein the glue layer is in a shape of a hemisphere, the light-adjusting element partially covers the glue layer, and an angle of the light-adjusting element covering the glue layer is less than or equal to 135 degrees.

13. The optical structure as claimed in claim 1, wherein a width of a top surface of the glue layer is greater than a width of a bottom surface of the glue layer.

14. An optical structure, comprising:
a substrate;
a light-emitting element disposed on the substrate;
a wavelength conversion layer covering the light-emitting element;
a glue layer covering the wavelength conversion layer; and
a light-adjusting element disposed on the glue layer,
wherein the refractive index of the wavelength conversion layer is greater than the refractive index of the glue layer, and a width of a top surface of the glue layer is greater than a width of a bottom surface of the glue layer.

15. The optical structure as claimed in claim 14, wherein the glue layer comprises a first portion and a second portion disposed on the first portion, wherein a side surface of the first portion is not coplanar with a side surface of the second portion.

16. The optical structure as claimed in claim 15, wherein an included angle between the side surface of the first portion and the bottom surface of the glue layer is greater than 90 degrees and less than or equal to 150 degrees.

17. The optical structure as claimed in claim 15, wherein an angle between the side surface of the second portion and the top surface of the glue layer is greater than or equal to 30 degrees and less than 90 degrees.

18. An optical structure, comprising:
a substrate;
a light-emitting element disposed on the substrate;
a wavelength conversion layer disposed on the light-emitting element;
a glue layer covering the wavelength conversion layer; and
an optical component disposed corresponding to the glue layer,
wherein the refractive index of the wavelength conversion layer is greater than the refractive index of the glue layer.

19. The optical structure as claimed in claim 18, wherein a ratio of height to width of the glue layer is greater than 0 and less than or equal to 0.5.

20. The optical structure as claimed in claim 18, wherein the optical component comprises a diffusion film, a wavelength conversion film disposed on the diffusion film, and a brightness enhancement film disposed on the wavelength conversion film.
